(19) United States
(12) Patent Application Publication
(10) Pub. No.: US 2026/0059865 A1
(43) Pub. Date: Feb. 26, 2026

(54) SEMICONDUCTOR DEVICE

(71) Applicant: Renesas Electronics Corporation, Tokyo (JP)

(72) Inventor: Koki NARITA, Tokyo (JP)

(21) Appl. No.: 19/250,455

(22) Filed: Jun. 26, 2025

(30) Foreign Application Priority Data
Aug. 23, 2024 (JP) 2024-142025

(51) Int. Cl. H10D 89/60

(52) U.S. Cl. CPC H10D 89/819

(57) ABSTRACT

A semiconductor device capable of improving the performance of an electrostatic protection circuit is provided. In semiconductor device 1, when trigger circuit 10 and trigger circuit 20 do not detect the application of ESD, switch SW11 electrically connects power node N12 and power node N13, switch SW12 electrically disconnects power node N11 and power node N13, switch SW13 electrically disconnects power node N12 and power node N14, and when trigger circuit 10 and trigger circuit 20 detect the application of ESD, switch SW11 electrically disconnects power node N12 and power node N13, switch SW12 electrically connects power node N11 and power node N13, and switch SW13 electrically connects power node N12 and power node N14.

### CROSS-REFERENCE TO RELATED APPLICATIONS

The disclosure of Japanese Patent Application No. 2024-142025 filed on Aug. 23, 2024, including the specification, drawings and abstract is incorporated herein by reference in its entirety.

### BACKGROUND

The present invention relates to a semiconductor device, specifically to a semiconductor device equipped with protection functions against ESD (Electro Static Discharge).

Semiconductor devices are equipped with electrostatic protection circuits to protect internal circuits from external electrostatic discharges.

Such electrostatic protection circuits typically comprise an RC timer, an inverter, and a protection transistor sized to discharge the applied ESD.

In recent years, as process miniaturization progresses, the breakdown voltage of elements decreases, but the voltage of external interfaces has not decreased. Therefore, for electrostatic protection of power supplies that are supplied with voltages higher than the element breakdown voltage, a configuration with stacked protection transistors is used to relax the voltage applied to each protection transistor to be below the element breakdown voltage.

There are disclosed techniques listed below.
[Patent Document 1]U.S. Pat. No. 5,907,464

Patent Document 1 discloses a configuration with stacked protection transistors, where a switch element is provided to short-circuit the power node and the intermediate node during ESD application, thereby raising the potential of the intermediate node to improve clamping performance.

### SUMMARY

However, in the circuit configuration described in Patent Document 1, if the potential of the intermediate node is too close to the power supply potential, the potential difference across the RC timer and the inverter becomes small, which may prevent the output of a normal signal to the corresponding protection transistor.

The embodiments described later were made in view of such issues, and other problems and novel features will become apparent from the description herein and the accompanying drawings.

A semiconductor device according to one embodiment includes a first protection transistor and a second protection transistor connected in series, a first trigger circuit connected between a first power node and a second power node to detect the application of electrostatic discharge and control the first protection transistor, and a second trigger circuit connected between a third power node and a fourth power node to detect the application of electrostatic discharge and control the second protection transistor. Furthermore, it includes a first switching circuit to switch the electrical connection or disconnection between the second power node and the third power node, a second switching circuit to switch the electrical connection or disconnection between the first power node and the third power node, and a third switching circuit to switch the electrical connection or disconnection between the second power node and the fourth power node. When the first trigger circuit and the second trigger circuit do not detect the application of electrostatic discharge, the first switching circuit electrically connects the second power node and the third power node, the second switching circuit electrically disconnects the first power node and the third power node, and the third switching circuit electrically disconnects the second power node and the fourth power node. Conversely, when the first trigger circuit and the second trigger circuit detect the application of electrostatic discharge, the first switching circuit electrically disconnects the second power node and the third power node, the second switching circuit electrically connects the first power node and the third power node, and the third switching circuit electrically connects the second power node and the fourth power node.

According to the embodiment, the performance of the electrostatic protection circuit can be improved.

### BRIEF DESCRIPTION OF THE DRAWINGS

FIG. 1 is a schematic circuit diagram of a semiconductor device according to the first embodiment.

FIG. 2 is a diagram showing an operation of the semiconductor device of FIG. 1.

FIG. 3 is a diagram showing an operation of the semiconductor device of FIG. 1.

FIG. 4 is a table summarizing the detection circuits or inverters connected to the gates when nMOS transistors and pMOS transistors are used for each switch.

FIG. 5 is a detailed circuit diagram of the semiconductor device in FIG. 1.

FIG. 6 is a circuit example in which the type of transistor used as a switch in the circuit of FIG. 5 is changed.

FIG. 7 is a table summarizing the detection circuits or inverters connected to the gates when nMOS transistors and pMOS transistors are used for each switch.

FIG. 8 is a modified example of the semiconductor device in FIG. 1.

FIG. 9 is a circuit example in which the type of transistor used as a switch in the circuit of FIG. 8 is changed.

FIG. 10 is a schematic circuit diagram of a semiconductor device according to the second embodiment.

FIG. 11 is a diagram showing an operation of the semiconductor device of FIG. 10.

FIG. 12 is a diagram showing an operation of the semiconductor device of FIG. 10.

FIG. 13 is a table summarizing the detection circuits or inverters connected to the gates when nMOS transistors and pMOS transistors are used for each switch.

FIG. 14 is a detailed circuit diagram of the semiconductor device in FIG. 10.

FIG. 15 is a circuit example in which the type of transistor used as a switch in the circuit of FIG. 14 is changed.

FIG. 16 is a table summarizing the detection circuits or inverters connected to the gates when nMOS transistors and pMOS transistors are used for each switch.

FIG. 17 is a modified example of the semiconductor device in FIG. 10.

FIG. 18 is a circuit example in which the type of transistor used as a switch in the circuit of FIG. 17 is changed.

FIG. 19 is a table summarizing the detection circuits or inverters connected to the gates when nMOS transistors and pMOS transistors are used for each switch.

FIG. 20 is a modified example of the semiconductor device in FIG. 10.

FIG. 21 is a table summarizing the detection circuits or inverters connected to the gates when nMOS transistors and pMOS transistors are used for each switch.

FIG. 22 is a modified example of the semiconductor device in FIG. 20.

FIG. 23 is a table summarizing the detection circuits or inverters connected to the gates when nMOS transistors and pMOS transistors are used for each switch in the semiconductor device according to the third embodiment.

FIG. 24 is a circuit diagram of the semiconductor device according to the third embodiment.

### DETAILED DESCRIPTION

In the following embodiments, for convenience, explanations may be divided into multiple sections or embodiments, when necessary, but unless specifically stated otherwise, they are not unrelated to each other; one may be a variation, detail, or supplementary explanation of the other. Additionally, in the following embodiments, when referring to the number of elements, etc. (including quantity, numerical values, amounts, ranges, etc.), unless specifically stated otherwise or clearly limited to a specific number in principle, it is not limited to that specific number and may be more or less than that specific number.

Furthermore, in the following embodiments, the constituent elements (including element steps, etc.) are not necessarily essential unless specifically stated otherwise or clearly considered essential in principle. Similarly, in the following embodiments, when referring to the shapes, positional relationships, etc., of components, unless specifically stated otherwise or clearly considered otherwise in principle, it is assumed to include those substantially approximate or similar to those shapes, etc. The same applies to the above numerical values and ranges.

The circuit elements constituting each functional block of the embodiment are not particularly limited but are formed on a semiconductor substrate such as single-crystal silicon using known integrated circuit technologies such as CMOS (complementary MOS transistors). In the embodiment, a MOSFET (Metal Oxide Semiconductor Field Effect Transistor) is used as an example of a MISFET (Metal Insulator Semiconductor Field Effect Transistor), but it does not exclude non-oxide films as gate insulating films. In the embodiment, a p-channel MOSFET and an n-channel MOSFET are referred to as pMOS transistors and nMOS transistors, respectively.

Hereinafter, embodiments of the present invention are described in detail with reference to the drawings. In all the drawings for explaining the embodiments, the same reference numerals are given to the same members in principle, and repetitive descriptions thereof are omitted.

### First Embodiment

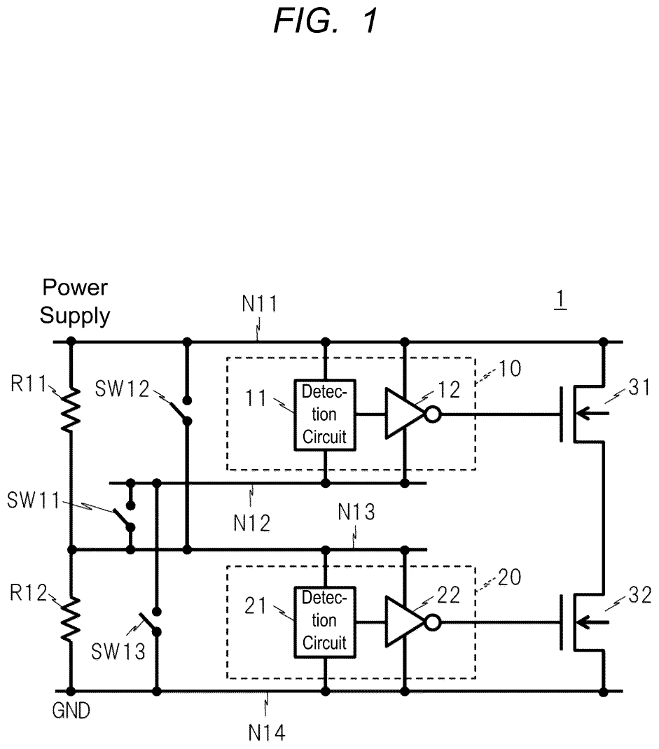

FIG. 1 shows a schematic diagram of a semiconductor device according to this embodiment. FIG. 1 is a schematic circuit diagram of the electrostatic protection circuit portion of the semiconductor device 1 according to this embodiment. The semiconductor device 1 includes resistors R11, R12, trigger circuits 10, 20, protection transistors 31, 32, and switches SW11, SW12, SW13.

Resistors R11 and R12 are connected in series between the power supply and GND. Resistors R11 and R12 divide the voltage between the power supply and GND and supply it to the power node N13. In FIG. 1, resistors R11 and R12 have the same resistance value, and the power node N13, which is the connection point of resistor R11 and resistor R12, is supplied with a voltage divided to ½ of the power supply voltage. Note that resistors R11 and R12 are not limited to resistor elements and may be configured with transistors. Also, as long as the inverter 12 can operate normally, the voltage division ratio by resistors R11 and R12 does not necessarily have to be ½ (1:1).

The power supply in FIG. 1 indicates a power supply line where a power supply voltage higher than GND in FIG. 1 (for example, Vdd) is supplied. Additionally, the power supply line in this embodiment is subjected to a voltage higher than the breakdown voltage of the standalone protective transistors 31 and 32. GND indicates a line where a power supply voltage lower than the power supply (also referred to as the reference potential) is supplied. In the description below, GND is assumed to be 0V, but it is not limited to 0V. Furthermore, each power supply node described below is a node that supplies the high potential side or low potential side power supply to the trigger circuits 10 and 20 and is different from the power supply line or GND except for some parts (wiring, etc.). The electrical connection or disconnect between each power supply node is controlled by switches described later.

The trigger circuit 10 includes a detection circuit 11 and an inverter 12. The detection circuit 11 detects the application of electrostatic discharge (hereinafter referred to as ESD) to the power supply line and outputs a detection signal to the inverter 12. The inverter 12 outputs a drive signal to the gate of the protective transistor 31 based on the detection signal. Additionally, the detection circuit 11 and the inverter 12 are connected between the power supply line (power supply node N11) and the power supply node N12. Here, the power supply node N11 is a node where the high potential side power supply voltage is applied to the detection circuit 11 and the inverter 12, and the power supply node N12 is a node where the low potential side (reference potential side) power supply voltage is applied to the detection circuit 11 and the inverter 12.

The trigger circuit 20 includes a detection circuit 21 and an inverter 22. The detection circuit 21 detects the application of ESD to the power supply line and outputs a detection signal to the inverter 22. The inverter 22 outputs a drive signal to the gate of the protective transistor 32 based on the detection signal. Additionally, the detection circuit 21 and the inverter 22 are connected between the power supply node N13 and GND (power supply node N14). Here, the power supply node N13 is a node where the high potential side power supply voltage is applied to the detection circuit 21 and the inverter 22, and the power supply node N14 is a node where the low potential side (reference potential side) power supply voltage is applied to the detection circuit 21 and the inverter 22.

The protective transistors 31 and 32 are composed of nMOS transistors and are connected in a series between the power supply and GND. In other words, the drain of the protective transistor 31 is connected to the power supply line, and the source of the protective transistor 31 is connected to the drain of the protective transistor 32. Then, the source of the protective transistor 32 is connected to GND. In other words, in FIG. 1, two protective transistors are stacked vertically. The protective transistors 31 and 32 turn on when the application of ESD to the power supply line is detected by trigger circuits 10 and 20 and discharge the current associated with the ESD application.

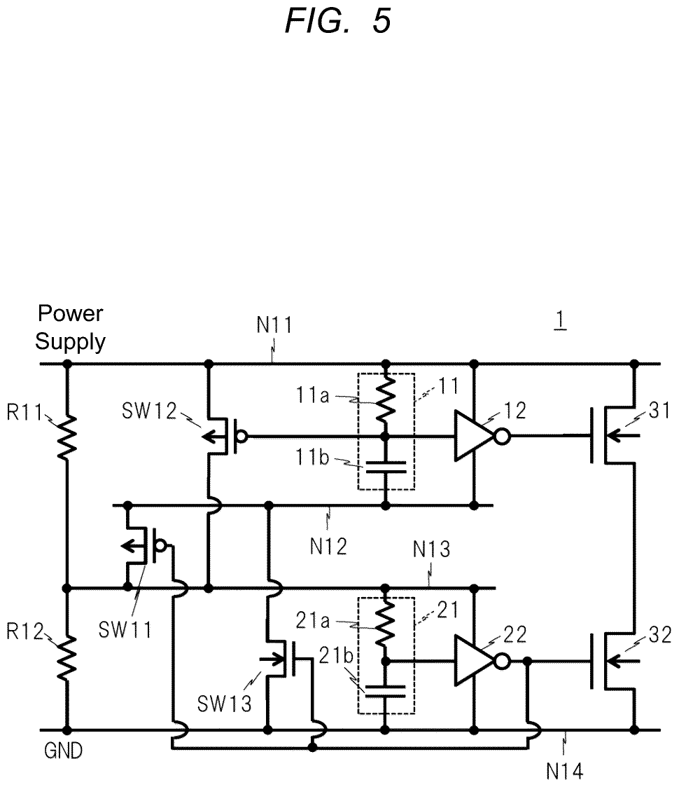

Switch SW11 electrically connects or disconnects the power supply node N12 and the power supply node N13. Switch SW12 electrically connects or disconnects the power supply node N11 (power supply line) and the power supply node N13. Switch SW13 electrically connects or disconnects the power supply node N12 and the power supply node N14 (GND). As shown in FIG. 5, switches SW11, SW12, and SW13 can be configured, for example, with transistors. Switches SW11, SW12, and SW13 are controlled to switch on or off by the output of the trigger circuits 10 and 20, as shown in FIG. 5.

That is, the configuration shown in FIG. 1 corresponds to the trigger circuit 10 as the first trigger circuit and the trigger circuit 20 as the second trigger circuit. Therefore, the detection circuit 11 corresponds to the first detection circuit, the inverter 12 corresponds to the first drive circuit, the detection circuit 21 corresponds to the second detection circuit, and the inverter 22 corresponds to the second drive circuit. Also, the power supply node N11 corresponds to the first power supply node, the power supply node N12 corresponds to the second power supply node, the power supply node N13 corresponds to the third power supply node, and the power supply node N14 corresponds to the fourth power supply node. Furthermore, switch SW11 corresponds to the first switching circuit, switch SW12 corresponds to the second switching circuit, and switch SW13 corresponds to the third switching circuit.

### Operation of the Present Embodiment

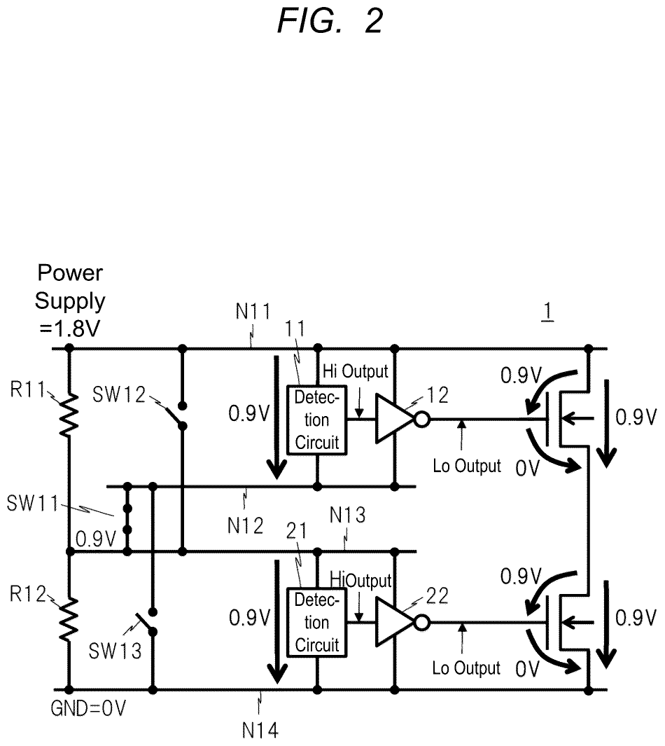

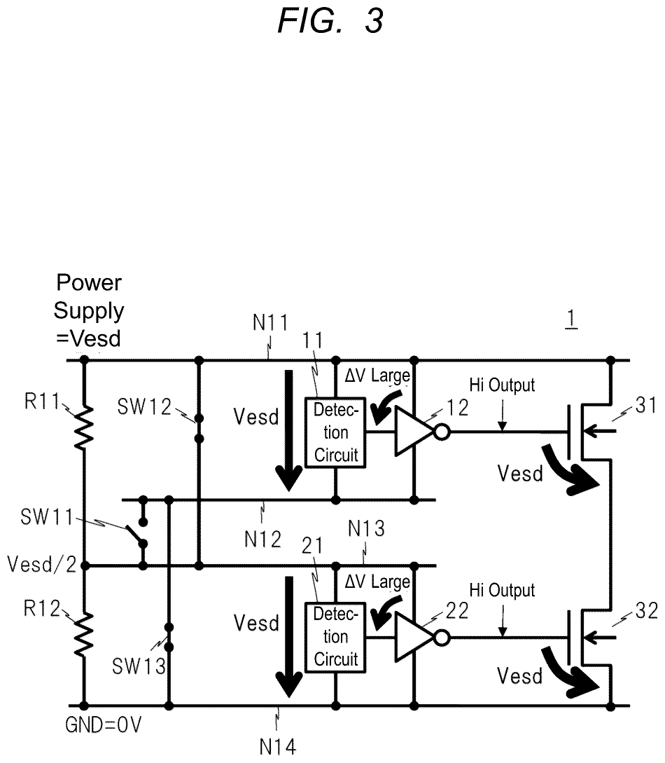

Next, the operation of the electrostatic protection circuit in the semiconductor device 1 with the above-described configuration will be described with reference to FIGS. 2 and 3. In FIGS. 2 and 3, GND is set to 0V, and when the power is turned on, a power supply of 1.8V is applied. Also, the breakdown voltage of the transistors used in this embodiment, including not only the protective transistors 31 and 32 but also the transistors functioning as switches, is set to less than 1.8V (for example, 1.2V).

FIG. 2 shows the state when the power is turned on (when ESD is not applied). When the power is turned on, the application of ESD is not detected by the detection circuits 11 and 21. Therefore, the detection circuits 11 and 21 output a Hi level, and the inverters 12 and 22 output a Lo level. As a result, the protective transistors 31 and 32 are turned off. At this time, switch SW11 is on, and switches SW12 and SW13 are off. Therefore, the power supply node N12 and the power supply node N13 are electrically connected, the power supply node N11 and the power supply node N13 are electrically disconnected, and the power supply node N12 and the power supply node N14 are electrically disconnected. As a result, an intermediate potential (0.9V) generated by the voltage divider circuit consisting of resistors R11 and R12 is supplied to the power supply nodes N12 and N13.

In the state of FIG. 2, the voltage across the detection circuit 11 (the voltage between the power supply node N11 and the power supply node N12) is 0.9V. Also, the drain-gate voltage of the protective transistor 31 is 0.9V, the gate-source voltage is 0V, and the drain-source voltage is 0.9V. Similarly, the voltage across the detection circuit 21 (the voltage between the power supply node N13 and the power supply node N14) is 0.9V. Also, the drain-gate voltage of the protective transistor 32 is 0.9V, the gate-source voltage is 0V, and the drain-source voltage is 0.9V. Therefore, when ESD is not applied, the breakdown voltage of the protective transistors 31 and 32 can be relaxed.

FIG. 3 shows the state when ESD is applied. When ESD is applied, a voltage Vesd is applied to the power supply line. Therefore, the voltage divider circuit also divides Vesd by ½. When ESD is applied, the detection circuits 11 and 21 output a Lo level indicating the application of ESD, and the inverters 12 and 22 output a Hi level. As a result, the protective transistors 31 and 32 are turned on and discharge the current associated with the application of ESD.

At this time, switch SW11 is off, and the SW12 and SW13 switches are on. Therefore, the power supply node N11 and the power supply node N13 are electrically connected, and the potential of the node (high potential side power supply node) where the high potential side power supply voltage is applied to the detection circuit 21 and the inverter 22 rises to the same level as the power supply line. Also, the power supply node N12 and the power supply node N14 are electrically connected, and the potential of the node (low potential side power supply node) where the low potential side power supply voltage is applied to the detection circuit 11 and the inverter 12 drops to the same level as GND. Meanwhile, the power supply node N12 and the power supply node N13 are electrically disconnected.

In the state of FIG. 3, the voltage across the detection circuit 11 (the voltage between the power supply node N11 and the power supply node N12) is Vesd. Therefore, the potential difference ΔV between the potential of the Lo level signal output by the detection circuit 11 and the power supply node N11 becomes large. Similarly, the voltage across the detection circuit 21 (the voltage between the power supply node N13 and the power supply node N14) is Vesd. Therefore, the potential difference ΔV between the potential of the Lo level signal output by the detection circuit 21 and the power supply node N13 becomes large. Also, the gate-source voltage Vgs of the protective transistors 31 and 32 becomes Vesd. Therefore, it is possible to secure the potential difference necessary for the operation of the trigger circuit 10, and it is also possible to increase the gate-source voltage Vgs of the protective transistors 31 and 32, thereby improving the clamping performance.

### Detailed Circuit of the Present Embodiment

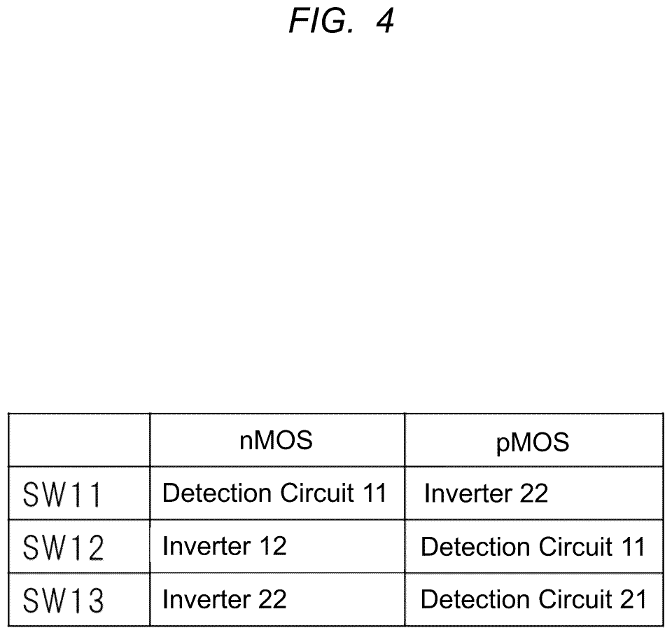

Next, a detailed circuit diagram of the configuration shown in FIG. 1 will be described. Switches SW11, SW12, and SW13 shown in FIG. 1 can be configured with transistors (MOSFETs) as shown in FIG. 5. In that case, each switch can be configured with either nMOS transistors or pMOS transistors but is limited to eight combinations shown in the table in FIG. 4 from the perspective of circuit operation and breakdown voltage.

Here, the perspective of circuit operation refers to whether a switch that should be on when ESD is applied can input a signal to the gate that allows it to operate correctly. Also, the perspective of breakdown voltage refers to ensuring that the breakdown voltage of the MOSFET functioning as a switch is not exceeded.

FIG. 4 summarizes in tabular form the detection circuit or inverter connected to the gate when each switch is configured with nMOS transistors or pMOS transistors. For example, in the circuit shown in FIG. 5, switch SW11 is configured with a pMOS transistor, and the output of the inverter 22 is connected to the gate. Also, switch SW12 is configured with a pMOS transistor, and the output of the detection circuit 11 is connected to the gate. Additionally, switch SW13 is configured with an nMOS transistor, and the output of the inverter 22 is connected to the gate.

That is, switch SW11 is switched based on the output signal of the detection circuit 11 or the inverter 22. Also, switch SW12 is switched based on the output signal of the detection circuit 11 or the inverter 12. Additionally, switch SW13 is switched based on the output signal of detection circuit 21 or inverter 22.

Furthermore, it is preferable that switch SW12 is a pMOS transistor as shown in FIG. 5. This is because the higher the gate-source voltage Vgs of the pMOS transistor, the easier it is for the potential on the drain side to rise. Similarly, it is preferable that switch SW13 is an nMOS transistor as shown in FIG. 5. This is because the higher the gate-source voltage Vgs of the nMOS transistor, the easier it is for the potential on the drain side to fall.

In the detailed circuit shown in FIG. 5, detection circuit 11 is composed of a resistive element 11a and a capacitive element 11b. The resistive element 11a and the capacitive element 11b are connected in series between power supply nodes N11 and N12. That is, one end of the resistive element 11a is connected to power supply node N11, and the other end is connected to one end of the capacitive element 11b. The other end of the capacitive element 11b is connected to power supply node N12. The connection point between the resistive element 11a and the capacitive element 11b is connected to the input of inverter 12.

Detection circuit 21 is composed of a resistive element 21a and a capacitive element 21b. The resistive element 21a and the capacitive element 21b are connected in series between power supply nodes N13 and N14. That is, one end of the resistive element 21a is connected to power supply node N13, and the other end is connected to one end of the capacitive element 21b. The other end of the capacitive element 21b is connected to power supply node N14. The connection point between the resistive element 21a and the capacitive element 21b is connected to the input of inverter 22.

Detection circuits 11 and 21 are well-known RC timers, with a time constant set to respond only in cases of high-speed slew rates such as ESD application.

Switch SW11 is composed of a pMOS transistor as described above. The source of switch SW11 is connected to power supply node N12, and the drain is connected to power supply node N13. The gate of switch SW11 is connected to the output of inverter 22. Switch SW11 turns on when inverter 22 outputs a low level. In other words, switch SW11 turns on when detection circuit 21 does not detect ESD application. When switch SW11 turns on, as described above, it electrically connects power supply nodes N12 and N13. Conversely, when detection circuit 21 detects ESD application and inverter 22 outputs a high level, switch SW11 turns off. When switch SW11 turns off, it electrically disconnects power supply nodes N12 and N13.

Switch SW12 is composed of a pMOS transistor as described above. The source of switch SW12 is connected to power supply node N11, and the drain is connected to power supply node N13. The gate of switch SW12 is connected to the connection point of resistive element 11a and capacitive element 11b, that is, the output of detection circuit 11. Switch SW12 turns on when detection circuit 11 outputs a low level. In other words, switch SW12 turns on when detection circuit 11 detects ESD application. When switch SW12 turns on, as described above, it electrically connects power supply nodes N11 and N13. Conversely, when detection circuit 11 does not detect ESD application and outputs a high level, switch SW12 turns off. When switch SW12 turns off, it electrically disconnects power supply nodes N11 and N13.

Switch SW13 is composed of an nMOS transistor as described above. The drain of switch SW13 is connected to the power supply node N12, and the source is connected to the power supply node N14. The gate of switch SW13 is connected to the output of inverter 22. Switch SW13 turns on when inverter 22 outputs a high level. In other words, switch SW13 turns on when detection circuit 21 detects ESD application. When switch SW13 turns on, as described above, it electrically connects power supply nodes N12 and N14. Conversely, when detection circuit 21 does not detect ESD application and inverter 22 outputs a low level, switch SW13 turns off. When switch SW13 turns off, it electrically disconnects power supply nodes N12 and N14.

### First Modified Example

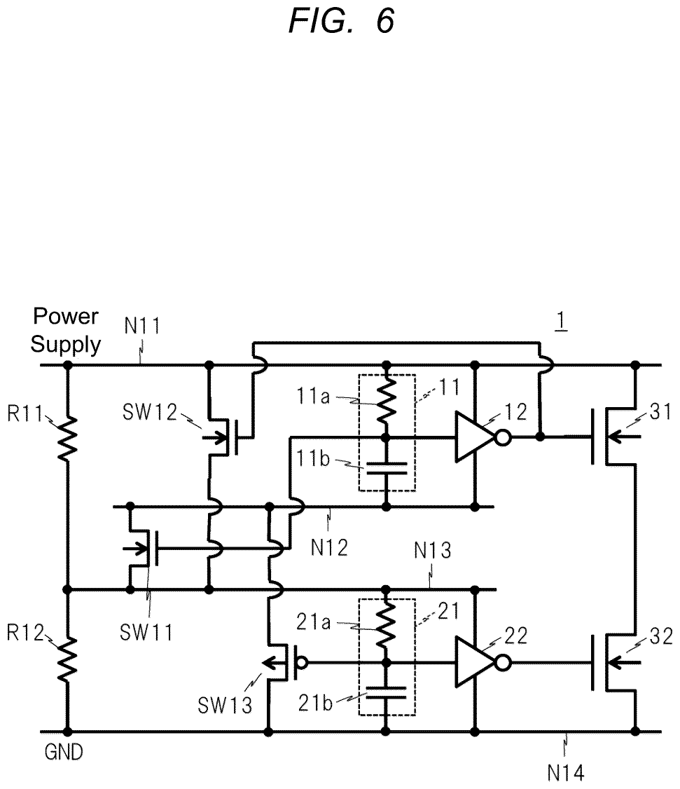

Next, a first modified example of this embodiment will be described. FIG. 6 is a circuit diagram in which each switch is configured with a type of MOSFET not used in FIG. 5, as shown in the table of FIG. 4. In other words, it is an example of another circuit configuration according to the table of FIG. 4. Of course, it goes without saying that a circuit configuration other than FIG. 6 may be used as long as it follows the table of FIG. 4. In FIG. 6, switch SW11 is composed of an nMOS transistor, and the gate is connected to the output of detection circuit 11. Switch SW12 is composed of an nMOS transistor, and the gate is connected to the output of inverter 12. Switch SW13 is composed of a pMOS transistor, and the gate is connected to the output of detection circuit 21.

The gate connection of switch SW11 is as described above, with the drain connected to power supply node N12 and the source connected to power supply node N13. Switch SW11 turns on when detection circuit 11 outputs a high level. In other words, switch SW11 turns on when detection circuit 11 does not detect ESD application.

The gate connection of switch SW12 is as described above, with the drain connected to power supply node N11 and the source connected to power supply node N13. Switch SW12 turns on when inverter 12 outputs a high level. In other words, switch SW12 turns on when detection circuit 11 detects ESD application.

The gate connection of switch SW13 is as described above, with the source connected to power supply node N12 and the drain connected to power supply node N14. Switch SW13 turns on when detection circuit 21 outputs a low level. In other words, switch SW13 turns on when detection circuit 21 detects ESD application.

### Second Modified Example

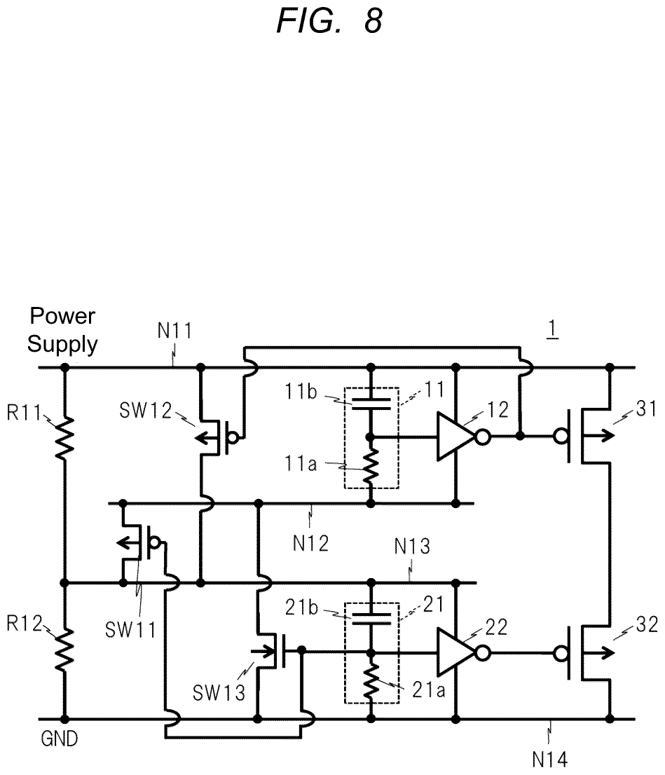

Next, a second modified example of this embodiment will be described. FIG. 8 is a circuit diagram in which protection transistors 31 and 32 are composed of pMOS transistors. In the circuit of FIG. 8, the configuration of detection circuits 11 and 21 and switches SW11, SW12, and SW13 differ from those in FIG. 5.

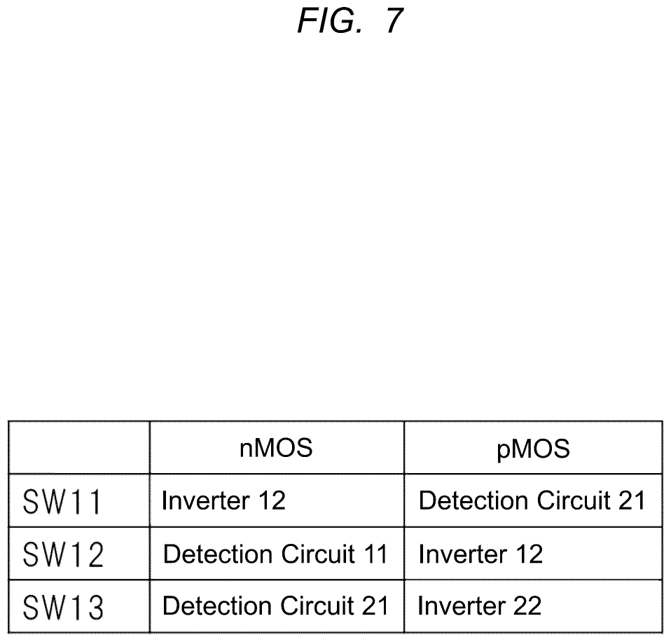

As explained in the table of FIG. 4, switches SW11, SW12, and SW13 can be composed of transistors (MOSFETs). This is the same even when protection transistors 31 and 32 are composed of pMOS transistors, and from the perspective of circuit operation and breakdown voltage, it is limited to the eight combinations shown in the table of FIG. 7.

FIG. 7 summarizes in tabular form the detection circuits or inverters connected to the gates when each switch is composed of nMOS or pMOS transistors, similar to FIG. 4. For example, in the circuit shown in FIG. 8, switch SW11 is composed of a pMOS transistor, and the gate is connected to the output of detection circuit 21. Switch SW12 is composed of a pMOS transistor, and the gate is connected to the output of inverter 12. Switch SW13 is composed of an nMOS transistor, and the gate is connected to the output of detection circuit 21.

That is, switch SW11 is switched based on the output signal of inverter 12 or detection circuit 21. Switch SW12 is switched based on the output signal of detection circuit 11 or inverter 12. Switch SW13 is switched based on the output signal of detection circuit 21 or inverter 22.

For the same reasons explained in FIG. 5, it is preferable that switch SW12 is a pMOS transistor as shown in FIG. 8. Similarly, it is preferable that switch SW13 is an nMOS transistor as shown in FIG. 8.

In detection circuit 11, the connection relationship between capacitive element 11b and resistive element 11a is reversed compared to FIG. 5. That is, one end of capacitive element 11b is connected to power supply node N11, and the other end is connected to one end of resistive element 11a. The other end of resistive element 11a is connected to power supply node N12. The connection point between capacitive element 11b and resistive element 11a is connected to the input of inverter 12.

In detection circuit 21, the connection relationship between capacitive element 21b and resistive element 21a is reversed compared to FIG. 5. That is, one end of capacitive element 21b is connected to power supply node N13, and the other end is connected to one end of resistive element 21a. The other end of resistive element 21a is connected to the power supply node N14. The connection point between capacitive element 21b and resistive element 21a is connected to the input of inverter 22.

Switch SW11 is composed of a pMOS transistor as described above. The source of switch SW11 is connected to power supply node N12, and the drain is connected to power supply node N13. The gate of switch SW11 is connected to the output of detection circuit 21. Switch SW11 turns on when detection circuit 21 outputs a low level. In other words, switch SW11 turns on when detection circuit 21 does not detect ESD application.

Switch SW12 is composed of a pMOS transistor as described above. The source of switch SW12 is connected to power node N11, and the drain is connected to power node N13. Additionally, the gate of switch SW12 is connected to the output of inverter 12. Switch SW12 turns on when inverter 12 outputs a Lo level. In other words, switch SW12 turns on when detection circuit 11 detects ESD application.

Switch SW13 is composed of an nMOS transistor as described above. The drain of switch SW13 is connected to power node N12, and the source is connected to power node N14. Additionally, the gate of switch SW13 is connected to the output of detection circuit 21. Switch SW13 turns on when detection circuit 21 outputs a Hi level. In other words, switch SW13 turns on when detection circuit 21 detects ESD application.

The circuit in FIG. 8, aside from changes in logic levels and some circuit modifications due to changing protection transistors 31, 32 to pMOS transistors, operate basically the same as the circuit in FIG. 5. That is, during ESD application, detection circuits 11, 21 output a Hi level indicating ESD application, and inverters 12, 22 output a Lo level. Therefore, protection transistors 31, 32 turn on and discharge the current associated with ESD application. During ESD application, switch SW12 turns on, causing the high potential side power node of trigger circuit 20 to rise to a potential similar to the power line, and switch SW13 turns on, causing the low potential side power node of trigger circuit 10 to drop to a potential similar to GND.

### Modified Example 3

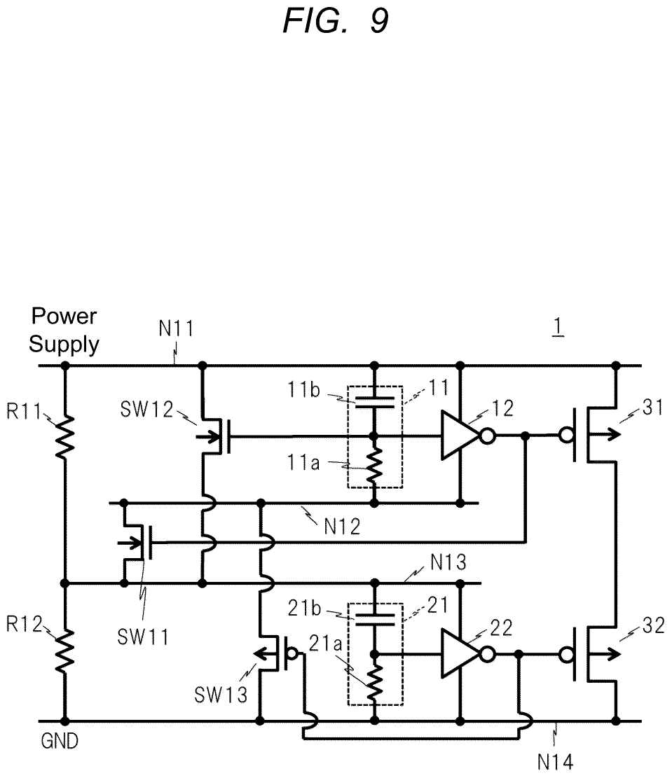

Next, Modified Example 3 of this embodiment will be described. FIG. 9 is a circuit diagram in which each switch is composed of a type of MOSFET not used in FIG. 8, according to the table in FIG. 7. In other words, it is an example of another circuit configuration according to the table in FIG. 7. Of course, any circuit configuration according to the table in FIG. 7 may be used, not limited to FIG. 9. In FIG. 9, switch SW11 is composed of an nMOS transistor, with the gate connected to the output of inverter 12. Additionally, switch SW12 is composed of an nMOS transistor, with the gate connected to the output of detection circuit 11. Furthermore, switch SW13 is composed of a pMOS transistor, with the gate connected to the output of inverter 22.

Switch SW11 has its gate connected as described above, with the drain connected to power node N12 and the source connected to power node N13. Switch SW11 turns on when inverter 12 outputs a Hi level. In other words, switch SW11 turns on when detection circuit 11 does not detect ESD application.

Switch SW12 has its gate connected as described above, with the drain connected to power node N11 and the source connected to power node N13. Switch SW12 turns on when detection circuit 11 outputs a Hi level. In other words, switch SW12 turns on when detection circuit 11 detects ESD application.

Switch SW13 has its gate connected as described above, with the source connected to power node N12 and the drain connected to power node N14. Switch SW13 turns on when inverter 22 outputs a Lo level. In other words, switch SW13 turns on when detection circuit 21 detects ESD application.

According to the above configuration, semiconductor device 1 can disconnect power node N12, which is the low potential side power node of trigger circuit 10, from power node N13, which is the high potential side power node of trigger circuit 20, during ESD application. Therefore, during ESD application, the potential of power node N12 can be lowered to a level similar to power node N14 (GND), and the potential of power node N13 can be raised to a level similar to power node N11 (power line). As a result, when protection transistors 31 and 32 are nMOS transistors, the potential of the high potential side power node of trigger circuit 20 can be raised while lowering the potential of the low potential side power node of trigger circuit 10 to ensure the necessary potential difference for the operation of trigger circuit 10. Additionally, when protection transistors 31, 32 are pMOS transistors, the gate-source voltage Vgs of protection transistor 31 can be increased while ensuring the potential difference applied to trigger circuit 20. Thus, the clamping performance of the electrostatic protection circuit can be improved.

Furthermore, since the high potential side power node (power node N13) of trigger circuit 20 and the low potential side power node (power node N12) of trigger circuit 10 are electrically separated into different nodes, raising the potential of power node N13 does not reduce the potential difference between power node N11 and power node N12. Therefore, it is unnecessary to precisely adjust the shunt capability of switch SW12 to ensure normal operation of detection circuit 11 and inverter 12, for example. Thus, design flexibility is improved.

Additionally, since trigger circuit 10 includes detection circuit 11 and inverter 12, and trigger circuit 20 includes detection circuit 11 and inverter 12, the channel current operation of protection transistors 31, 32 can allow current associated with ESD application to flow. Therefore, the internal circuit of semiconductor device 1 can be protected.

Moreover, when protection transistors 31 and 32 are composed of nMOS transistors, switch SW11 is switched based on the output of detection circuit 11 or inverter 22, switch SW12 is switched based on the output of detection circuit 11 or inverter 12, and switch SW13 is switched based on the output of detection circuit 21 or inverter 22. When protection transistors 31, 32 are composed of pMOS transistors, switch SW11 is switched based on the output of detection circuit 21 or inverter 12, switch SW12 is switched based on the output of detection circuit 11 or inverter 12, and switch SW13 is switched based on the output of detection circuit 21 or inverter 22. Therefore, appropriate signals among those generated by trigger circuits 10, 20 can be utilized from the perspective of circuit operation and voltage resistance, facilitating the control of switches SW11, SW12, and SW13.

Additionally, since switch SW12 is composed of a pMOS transistor and switch SW13 is composed of an nMOS transistor, for example, when the source is connected to the power line as in switch SW12, the drain side potential can be easily raised. Similarly, when the source is connected to GND as in switch SW13, the drain side potential can be easily lowered.

### Second Embodiment

Next, the second embodiment will be described. In the following, explanations of overlapping parts with the aforementioned embodiment will be omitted in principle.

### Challenges of this Embodiment

For example, in the circuit of FIG. 5, when ESD is detected, switch SW12 turns on, causing the potential of power node N13 to rise. Consequently, the potential at the output of detection circuit 21 (connection point of resistor element 21a and capacitance element 21b) rises. As a result, the gate-source voltage Vgs of the nMOS transistor constituting inverter 22 increases, making the output of inverter 22 more likely to invert. The increased likelihood of inverter 22's output inverting means that protection transistor 32 is more likely to turn off, potentially shortening the period during which protection transistor 32 is on.

Additionally, in the circuit of FIG. 5, when ESD is detected, switch SW13 turns on, causing the potential of power node N12 to drop to the GND level. Consequently, the gate-source voltage Vgs of the nMOS transistor constituting inverter 12 increases, making the output of inverter 12 more likely to invert. The increased likelihood of inverter 12's output inverting means that protection transistor 31 is more likely to turn off, potentially shortening the period during which protection transistor 31 is on.

Thus, in the circuit of FIG. 5, there may be cases where the period during which protection transistors 31, 32 are on is shorter than expected.

### Configuration of this Embodiment

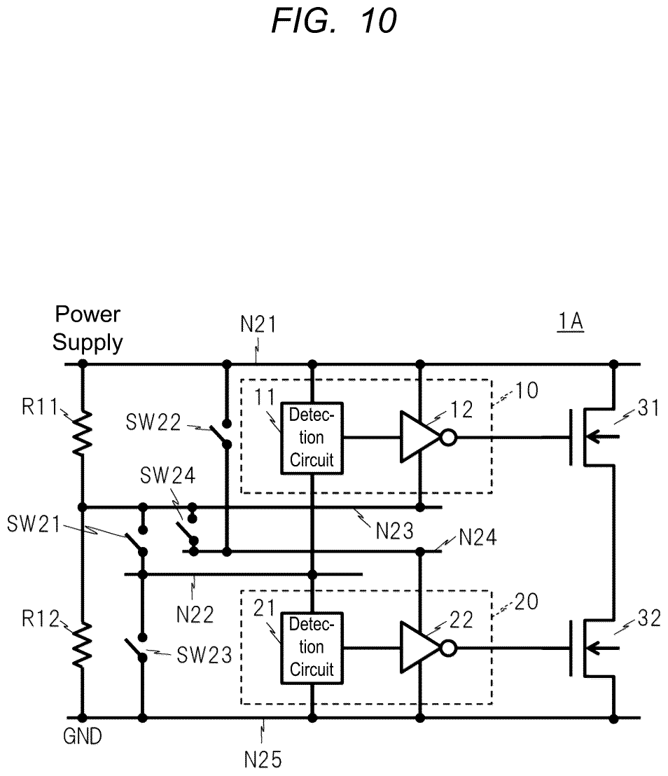

A schematic diagram of the semiconductor device according to this embodiment is shown in FIG. 10. FIG. 10 is a schematic circuit diagram of the electrostatic protection circuit portion of semiconductor device 1A according to this embodiment. Semiconductor device 1A includes resistors R11, R12, trigger circuits 10, 20, protection transistors 31, 32, and switches SW21, SW22, SW23, SW24.

The resistors R11, R12, trigger circuits 10, 20, and protection transistors 31, 32 shown in FIG. 10 are basically the same as those in FIG. 1. However, the connection relationships to each power node are different. Resistors R11 and R12 divide the voltage between the power supply and GND and supply it to power node N23.

Detection circuit 11 of trigger circuit 10 is connected between the power line (power node N21) and power node N22. Power node N21 is the high potential side power node for detection circuit 11 and inverter 12, and power node N22 is the low potential side power node for detection circuit 11. In addition, inverter 12 of trigger circuit 10 is connected between the power supply node N21 and the power supply node N23. The power supply node N23 is the low potential side power supply node for the inverter 12.

The detection circuit 21 of the trigger circuit 20 is connected between the power supply node N22 and GND (power supply node N25). The power supply node N22 is common with the low potential side power supply node of the detection circuit 11 and is also the high potential side power supply node of the detection circuit 21. The power supply node N25 is the low potential side power supply node for detection circuit 21 and the inverter 22. Additionally, the inverter 22 of the trigger circuit 20 is connected between the power supply node N24 and the power supply node N25. The power supply node N24 is the high potential side power supply node for the inverter 22.

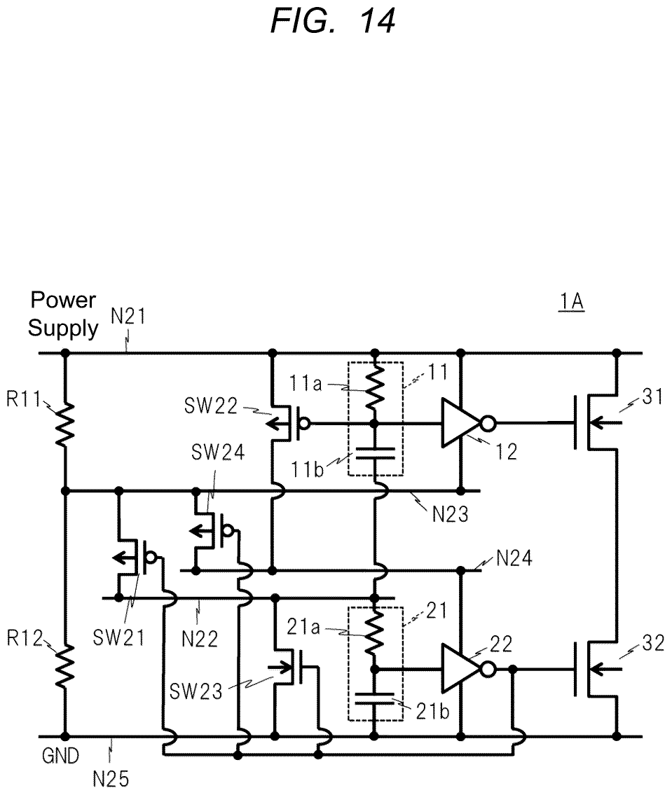

Switch SW21 electrically connects or disconnects the power supply node N23 and the power supply node N22. Switch SW22 electrically connects or disconnects the power supply node N21 and the power supply node N24. Switch SW23 electrically connects or disconnects the power supply node N22 and the power supply node N25. Switch SW24 electrically connects or disconnects the power supply node N23 and the power supply node N24. As shown in FIG. 14, switches SW21, SW22, SW23, and SW24 can be configured, for example, with transistors. Switches SW21, SW22, SW23, and SW24 are controlled to switch on or off by the output of the trigger circuits 10 and 20, as shown in FIG. 14.

As described above, in this embodiment, the low potential side power supply nodes of the detection circuit 11 and the inverter 12 are separated, and the high potential side power supply nodes of the detection circuit 21 and the inverter 22 are separated.

That is, the configuration shown in FIG. 10 corresponds to the trigger circuit 10 as the first trigger circuit and the trigger circuit 20 as the second trigger circuit. Therefore, the detection circuit 11 corresponds to the first detection circuit, the inverter 12 corresponds to the first drive circuit, the detection circuit 21 corresponds to the second detection circuit, and the inverter 22 corresponds to the second drive circuit. Additionally, the power supply node N21 corresponds to the first and third power supply nodes, the power supply node N22 corresponds to the second power supply node, the power supply node N23 corresponds to the fourth power supply node, the power supply node N24 corresponds to the sixth power supply node, and the power supply node N25 corresponds to the fifth and seventh power supply nodes. Furthermore, switch SW21 corresponds to the first switching circuit, switch SW22 corresponds to the second switching circuit, switch SW23 corresponds to the third switching circuit, and switch SW24 corresponds to the fourth switching circuit.

### Operation of the Present Embodiment

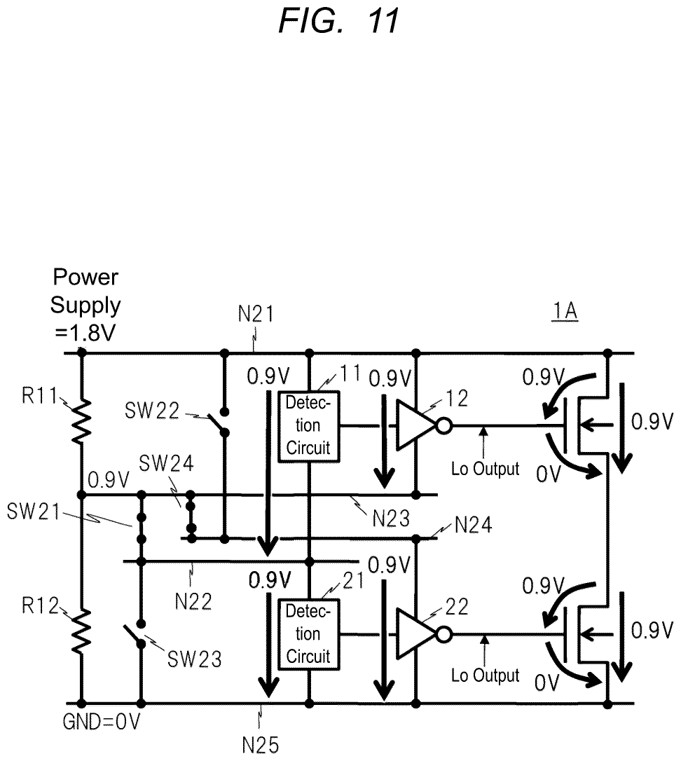

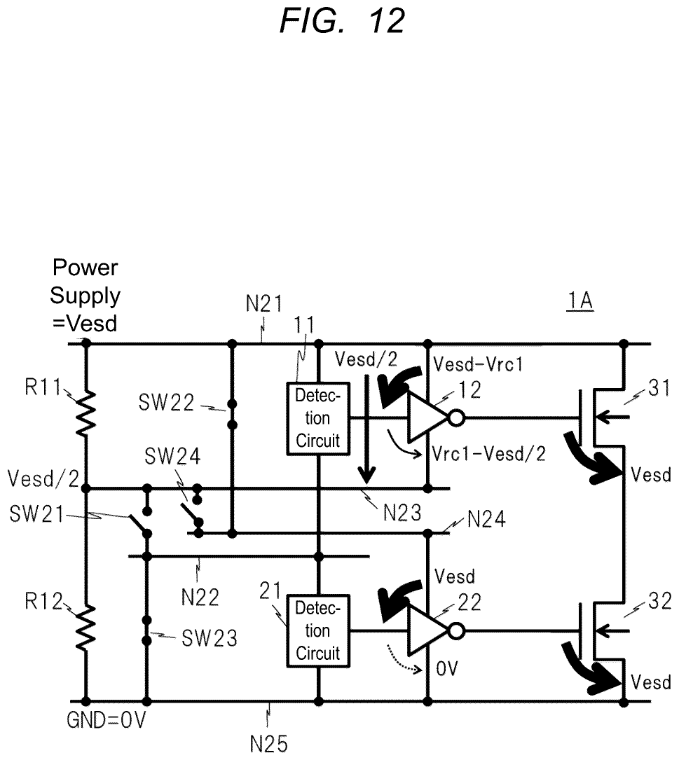

Next, the operation of the electrostatic protection circuit with the above-described configuration will be explained with reference to FIGS. 11 and 12. In FIGS. 11 and 12, GND is set to 0V, and when the power is turned on, a power supply of 1.8V is applied. Also, similar to the first embodiment, the breakdown voltage of the transistors used in this embodiment, including not only the protection transistors 31 and 32 but also the transistors functioning as switches, is set to less than 1.8V (for example, 1.2V).

FIG. 11 shows the state of when the power is turned on (when ESD is not applied). When the power is turned on, ESD application is not detected by the detection circuits 11 and 21. Therefore, the detection circuits 11 and 21 output a high level, and the inverters 12 and 22 output a low level. As a result, the protection transistors 31 and 32 are turned off. At this time, switches SW21 and SW24 are on, and switches SW22 and SW23 are off. Therefore, the power supply nodes N22, N23, and N24 are electrically connected, the power supply node N21 and the power supply node N24 are electrically disconnected, and the power supply node N22 and the power supply node N25 are electrically disconnected. As a result, an intermediate potential (0.9V) generated by the voltage divider circuit consisting of resistors R11 and R12 is supplied to the power supply nodes N22, N23, and N24.

In the state of FIG. 11, the voltage across the detection circuit 11 (the voltage between the power supply node N21 and the power supply node N22) is 0.9V. Similarly, the voltage across the inverter 12 (the voltage between the power supply node N21 and the power supply node N23) is also 0.9V. Additionally, the drain-gate voltage of the protection transistor 31 is 0.9V, the gate-source voltage is 0V, and the drain-source voltage is 0.9V. Similarly, the voltage across the detection circuit 21 (the voltage between the power supply node N22 and the power supply node N25) is 0.9V. The voltage across the inverter 22 (the voltage between the power supply node N24 and the power supply node N25) is also 0.9V. The drain-gate voltage of the protection transistor 32 is 0.9V, the gate-source voltage is 0V, and the drain-source voltage is 0.9V. Therefore, when ESD is not applied, the breakdown voltage relaxation of the protection transistors 31 and 32 can be achieved.

FIG. 12 shows the state when ESD is applied. When ESD is applied, a voltage Vesd is applied to the power supply line. Therefore, the voltage divider circuit also divides Vesd by half. When ESD is applied, the detection circuits 11 and 21 output a low level indicating ESD application, and the inverters 12 and 22 output a high level. As a result, the protection transistors 31 and 32 are turned on and discharge the current associated with ESD application.

At this time, switches SW21 and SW24 are off, and switches SW22 and SW23 are on. Therefore, the power supply node N21 and the power supply node N24 are electrically connected, and the potential of the high potential side power supply node of the inverter 22 rises to approximately the same level as the power supply line. Additionally, the power supply node N22 and the power supply node N25 are electrically connected, and the potential of the low potential side power supply node of the detection circuit 11 and the high potential side of the detection circuit 21 decreases to approximately the same level as GND. Meanwhile, the power supply node N23 and the power supply node N22 are electrically disconnected, and the power supply node N23 and the power supply node N24 are electrically disconnected. Furthermore, the potential of the low potential side power supply node (power supply node N23) of the inverter 12 is applied with the output potential of the voltage divider circuit (Vesd/2).

In the state of FIG. 12, the voltage across the inverter 12 (the voltage between the power supply node N21 and the power supply node N23) is Vesd/2. If the potential of the output signal of the detection circuit 11 is Vrc1, in the inverter 12, the source-gate voltage of the pMOS transistor becomes Vesd−Vrc1, while the source-gate voltage of the nMOS transistor becomes Vrc1−Vesd/2. When ESD is detected, since the inverter 12 outputs a high level, the output Vrc1 of the detection circuit 11 outputs a low level, and its potential becomes 0V (or a potential close to 0V). Therefore, the above-mentioned Vesd−Vrc1 becomes a relatively large potential difference, while Vrc1−Vesd/2 becomes a small potential difference. In this way, when ESD is applied, the potential of the low potential side power supply node of the inverter 12 is not excessively lowered, so the gate-source voltage Vgs of the nMOS transistor constituting the inverter 12 is suppressed from expanding, and the high output of the inverter 12 can be maintained.

Additionally, in the state of FIG. 12, in inverter 22, the source-gate voltage of the pMOS transistor is Vesd, while the source-gate voltage of the nMOS transistor is CV. Therefore, while keeping the potential of the high potential side power supply node of the inverter 22 elevated, the potential of the high potential side power supply node of the detection circuit 21 can be lowered. Therefore, the high output of the inverter 22 can be maintained.

### Detailed Circuit of the Present Embodiment

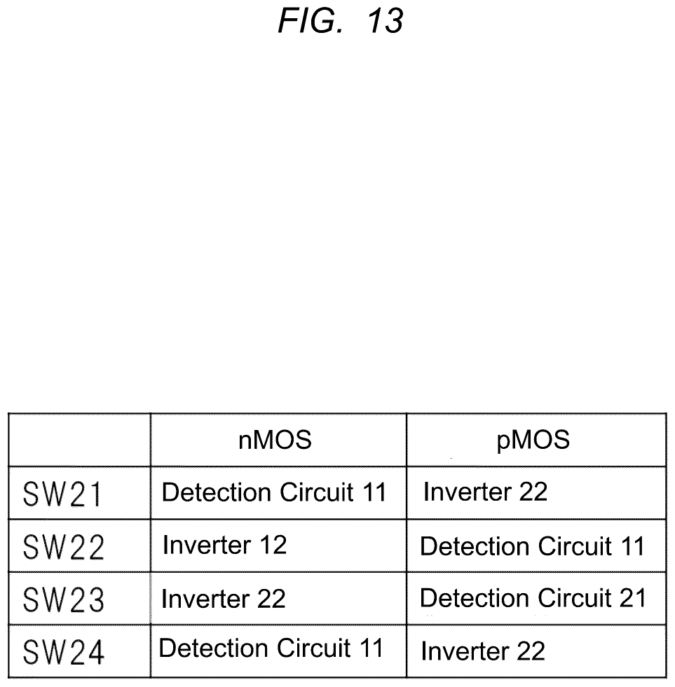

Next, a detailed circuit diagram of the configuration shown in FIG. 10 will be described. As explained in the first embodiment, switches SW21, SW22, SW23, and SW24 shown in FIG. 10 can be configured with transistors (MOSFETs) as shown in FIG. 14. In that case, each switch can be configured with either nMOS or pMOS transistors, but from the perspective of circuit operation and breakdown voltage, it is limited to 16 combinations shown in the table in FIG. 13.

FIG. 13 summarizes in tabular form the detection circuit or inverter connected to the gate when each switch is configured with nMOS or pMOS transistors. For example, in the circuit shown in FIG. 14, switch SW21 is configured with a pMOS transistor, and the output of the inverter 22 is connected to the gate. Similarly, switch SW22 is configured with a pMOS transistor, and the output of the detection circuit 11 is connected to the gate. Switch SW23 is configured with an nMOS transistor, and the output of the inverter 22 is connected to the gate. Switch SW24 is configured with a pMOS transistor, and the output of the inverter 22 is connected to the gate.

That is, switch SW21 is switched based on the output signal of the detection circuit 11 or the inverter 22. Similarly, switch SW22 is switched based on the output signal of the detection circuit 11 or the inverter 12. Switch SW23 is switched based on the output signal of the detection circuit 21 or the inverter 22. Switch SW24 is switched based on the output signal of the detection circuit 11 or the inverter 22.

Also, for the same reasons explained in the first embodiment, it is preferable that switch SW12 is a pMOS transistor as shown in FIG. 14. Similarly, it is preferable that switch SW13 is an nMOS transistor as shown in FIG. 14.

In the detailed circuit shown in FIG. 14, the detection circuit 11 is composed of a resistor element 11a and a capacitor element 11b. The resistor element 11a and the capacitor element 11b are connected in series between the power supply node N21 and the power supply node N22. In other words, one end of the resistor element 11a is connected to the power supply node N21, and the other end is connected to one end of the capacitor element 11b. The other end of the capacitance element 11b is connected to the power supply node N22. The connection point between the resistance element 11a and the capacitance element 11b is connected to the input of the inverter 12.

The detection circuit 21 consists of a resistor element 21a and a capacitance element 21b. The resistor element 21a and the capacitance element 21b are connected in series between the power supply node N22 and the power supply node N25. In other words, one end of the resistor element 21a is connected to the power supply node N22, and the other end is connected to one end of the capacitance element 21b. The other end of the capacitance element 21b is connected to the power supply node N25. The connection point between the resistor element 21a and the capacitance element 21b is connected to the input of the inverter 22.

Switch SW21 is composed of a pMOS transistor as described above. The source of switch SW21 is connected to the power supply node N23, and the drain is connected to the power supply node N22. Additionally, the gate of switch SW21 is connected to the output of the inverter 22. Switch SW21 turns on when the inverter 22 outputs a low level. In other words, switch SW21 turns on when the detection circuit 21 does not detect ESD application. When switch SW21 turns on, as described above, it electrically connects the power supply node N23 and the power supply node N22. On the other hand, when the detection circuit 21 detects ESD application and the inverter 22 outputs a high level, it turns off. When switch SW21 turns off, it electrically disconnects the power supply node N23 and the power supply node N22.

Switch SW22 is composed of a pMOS transistor as described above. The source of switch SW22 is connected to the power supply node N21, and the drain is connected to the power supply node N24. Additionally, the gate of switch SW22 is connected to the connection point of the resistance element 11a and the capacitance element 11b, that is, the output of the detection circuit 11. Switch SW22 turns on when the detection circuit 11 outputs a low level. In other words, switch SW22 turns on when the detection circuit 11 detects ESD application. When switch SW22 turns on, as described above, it electrically connects the power supply node N21 and the power supply node N24. On the other hand, when the detection circuit 11 does not detect ESD application, it outputs a high level, turning off the switch. When switch SW22 turns off, it electrically disconnects the power supply node N21 and the power supply node N24.

Switch SW23 is composed of an nMOS transistor as described above. The drain of switch SW23 is connected to the power supply node N22, and the source is connected to the power supply node N25. Additionally, the gate of switch SW23 is connected to the output of the inverter 22. Switch SW23 turns on when the inverter 22 outputs a high level. In other words, switch SW23 turns on when the detection circuit 21 detects ESD application. When switch SW23 turns on, as described above, it electrically connects the power supply node N22 and the power supply node N25. On the other hand, when the detection circuit 21 does not detect ESD application and the inverter 22 outputs a low level, it turns off. When switch SW23 turns off, it electrically disconnects the power supply node N22 and the power supply node N25.

Switch SW24 is composed of a pMOS transistor as described above. The source of switch SW24 is connected to the power supply node N23, and the drain is connected to the power supply node N24. Additionally, the gate of switch SW24 is connected to the output of the inverter 22. Switch SW24 turns on when the inverter 22 outputs a low level. In other words, switch SW24 turns on when the detection circuit 21 does not detect ESD application. When switch SW24 turns on, as described above, it electrically connects the power supply node N23 and the power supply node N24. On the other hand, when the detection circuit 21 detects ESD application and the inverter 22 outputs a high level, it turns off. When switch SW24 turns off, it electrically disconnects the power supply node N23 and the power supply node N24.

### First Modified Example

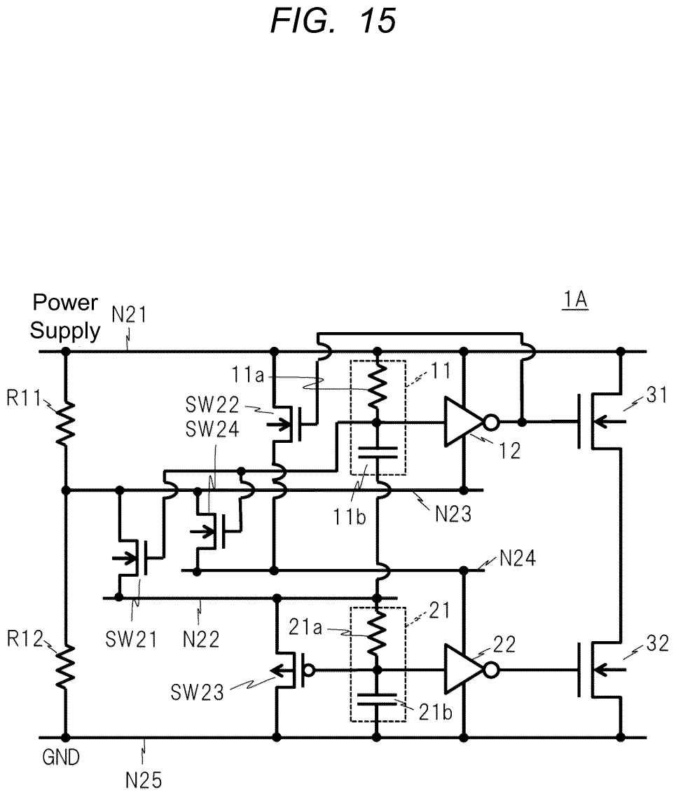

Next, a first modified example of this embodiment will be described. FIG. 15 is a circuit diagram in which each switch is configured with a type of MOSFET not used in FIG. 14, as shown in the table of FIG. 13. In other words, it is an example of another circuit configuration according to the table of FIG. 14. Of course, any circuit configuration according to the table of FIG. 14 may be used, not limited to the configuration of FIG. 15. In FIG. 15, switch SW21 is composed of an nMOS transistor, and the gate is connected to the output of the detection circuit 11. Additionally, switch SW22 is composed of an nMOS transistor, and the gate is connected to the output of the inverter 12. Additionally, switch SW23 is composed of a pMOS transistor, and the gate is connected to the output of the detection circuit 21. Additionally, switch SW24 is composed of an nMOS transistor, and the gate is connected to the output of the detection circuit 11.

Switch SW21 has the gate connection as described above, with the drain connected to the power supply node N23 and the source connected to the power supply node N22. Switch SW21 turns on when the detection circuit 11 outputs a high level. In other words, switch SW21 turns on when the detection circuit 11 does not detect ESD application.

Switch SW22 has the gate connection as described above, with the drain connected to the power supply node N21 and the source connected to the power supply node N24. Switch SW22 turns on when the inverter 12 outputs a high level. In other words, switch SW12 turns on when the detection circuit 11 detects ESD application.

Switch SW23 has the gate connection as described above, with the source connected to the power supply node N22 and the drain connected to the power supply node N25. Switch SW23 turns on when the detection circuit 21 outputs a low level. In other words, switch SW13 turns on when the detection circuit 21 detects ESD application.

Switch SW24 has the gate connection as described above, with the drain connected to the power supply node N23 and the source connected to the power supply node N24. Switch SW24 turns on when the detection circuit 11 outputs a high level. In other words, switch SW24 turns on when the detection circuit 21 does not detect ESD application.

### Second Modified Example

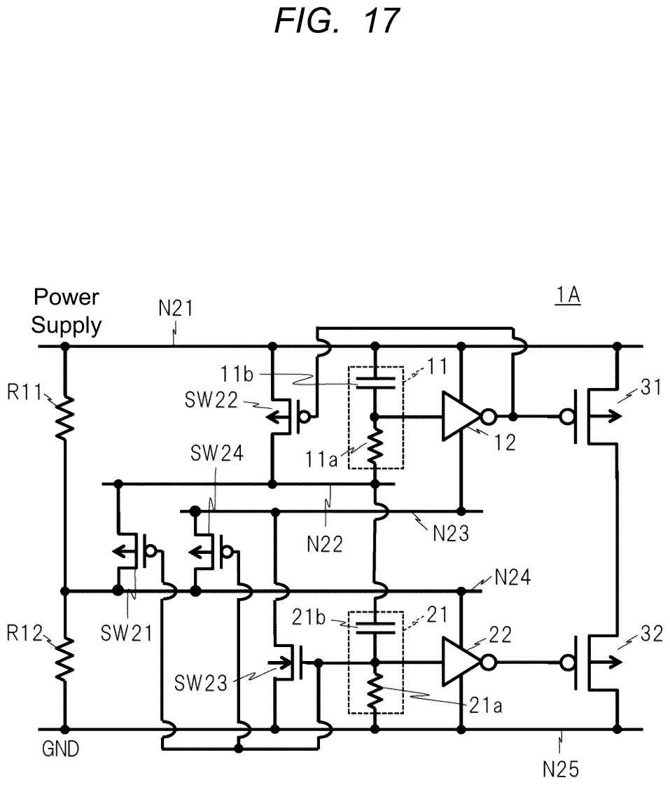

Next, a second modified example of this embodiment will be described. FIG. 17 is a circuit diagram in which the protection transistors 31 and 32 are composed of pMOS transistors in the circuit of FIG. 14. In the circuit FIG. 17, the configuration of the detection circuits 11, 21 and switches SW21, SW22, SW23, SW24 differ from those in FIG. 14.

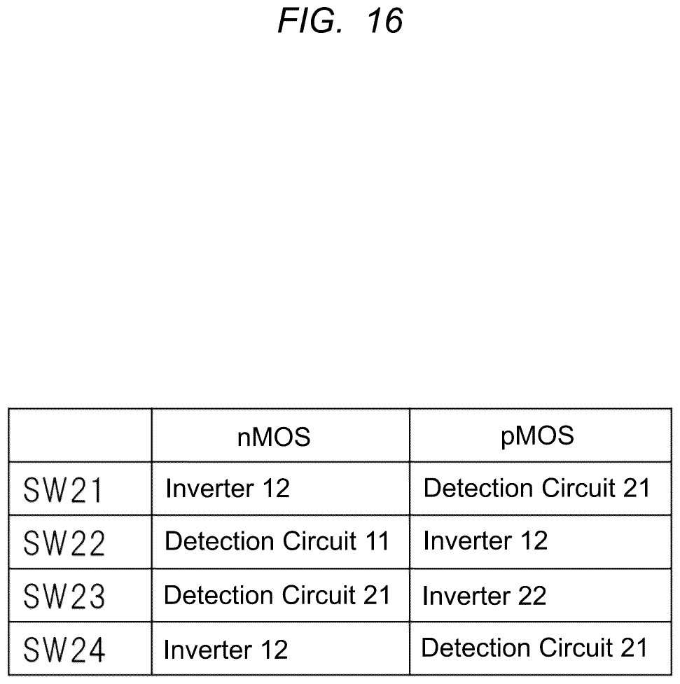

As described in the table of FIG. 13, switches SW21, SW22, SW23, SW24 can be composed of transistors (MOSFETs). This is the same even when the protection transistors 31 and 32 are composed of pMOS transistors, and from the perspective of circuit operation and withstand voltage, it is limited to the 16 combinations shown in the table of FIG. 16.

FIG. 16 summarizes in tabular form the detection circuits or inverters connected to the gates when each switch is composed of nMOS transistors or pMOS transistors, similar to FIG. 13. For example, in the circuit shown in FIG. 17, switch SW21 is composed of a pMOS transistor, and the gate is connected to the output of the detection circuit 21. Additionally, switch SW22 is composed of a pMOS transistor, and the gate is connected to the output of the inverter 12. Additionally, switch SW23 is composed of an nMOS transistor, and the gate is connected to the output of the detection circuit 21. Additionally, switch SW24 is composed of a pMOS transistor, and the gate is connected to the output of the detection circuit 21.

That is, switch SW21 is switched based on the output signal of the inverter 12 or the detection circuit 21. Additionally, switch SW22 is switched based on the output signal of the detection circuit 11 or the inverter 12. Additionally, switch SW23 is switched based on the output signal of the detection circuit 21 or the inverter 22. Additionally, switch SW24 is switched based on the output signal of the inverter 12 or the detection circuit 21.

Also, for the same reasons as described in the first embodiment, it is preferable that switch SW22 is a pMOS transistor as shown in FIG. 16. Additionally, it is preferable that switch SW23 is an nMOS transistor as shown in FIG. 16.

In the detection circuit 11, the connection relationship between the capacitance element 11b and the resistance element 11a is reversed from that in FIG. 14. That is, one end of the capacitance element 11b is connected to the power supply node N21, and the other end is connected to one end of the resistance element 11a. The other end of the resistance element 11a is connected to the power supply node N22. Then, the connection point between the capacitance element 11b and the resistance element 11a is connected to the input of the inverter 12.

In the detection circuit 21, the connection relationship between the capacitance element 21b and the resistance element 21a is reversed from that in FIG. 14. That is, one end of the capacitance element 21b is connected to the power supply node N22, and the other end is connected to one end of the resistance element 21a. The other end of the resistance element 21a is connected to the power supply node N25. Then, the connection point between the capacitance element 21b and the resistance element 21a is connected to the input of the inverter 22.

Switch SW21 is composed of a pMOS transistor as described above. The source of switch SW21 is connected to the power supply node N22, and the drain is connected to the power supply node N24. The gate of switch SW21 is connected to the output of detection circuit 21. Switch SW21 turns on when the detection circuit 21 outputs a Lo level. In other words, switch SW21 turns on when the detection circuit 21 does not detect ESD application.

Switch SW22 is composed of a pMOS transistor as described above. The source of switch SW22 is connected to the power supply node N21, and the drain is connected to the power supply node N22. The gate of switch SW22 is connected to the output of the inverter 12. Switch SW22 turns on when the inverter 12 outputs a Lo level. In other words, switch SW22 turns on when the detection circuit 11 detects ESD application.

Switch SW23 is composed of an nMOS transistor as described above. The drain of switch SW23 is connected to the power supply node N23, and the source is connected to the power supply node N25. The gate of switch SW23 is connected to the output of the detection circuit 21. Switch SW23 turns on when the detection circuit 21 outputs a Hi level. In other words, switch SW23 turns on when the detection circuit 21 detects ESD application.

Switch SW24 is composed of a pMOS transistor as described above. The source of switch SW24 is connected to the power supply node N23, and the drain is connected to the power supply node N24. The gate of switch SW24 is connected to the output of the detection circuit 21. Switch SW24 turns on when the detection circuit 21 outputs a Lo level. In other words, switch SW24 turns on when the detection circuit 21 does not detect ESD application.

The circuit in FIG. 17, except for changes in logic levels and some circuit modifications due to changing the protection transistors 31, 32 to pMOS transistors, operates basically the same as the circuit in FIG. 14. In other words, during ESD application, the detection circuits 11, 21 output a Hi level indicating ESD application, and the inverters 12, 22 output a Lo level. Therefore, the protection transistors 31, 32 turn on and discharge the current associated with ESD application. The circuit in FIG. 17 can achieve the same effect as the circuit in FIG. 14.

The configuration shown in FIG. 17 corresponds to the detection circuit 21 as the first detection circuit, the inverter 22 as the first drive circuit, the detection circuit 11 as the second detection circuit, and the inverter 12 as the second drive circuit. Therefore, the trigger circuit 20 corresponds to the first trigger circuit, and the trigger circuit 10 corresponds to the second trigger circuit. Additionally, the power supply node N25 corresponds to the first and third power supply nodes, the power supply node N22 to the second power supply node, the power supply node N24 to the fourth power supply node, the power supply node N23 to the sixth power supply node, and the power supply node N21 to the fifth and seventh power supply nodes. Furthermore, switch SW21 corresponds to the first switching circuit, switch SW23 to the second switching circuit, switch SW22 to the third switching circuit, and switch SW24 to the fourth switching circuit.

### Third Modified Example

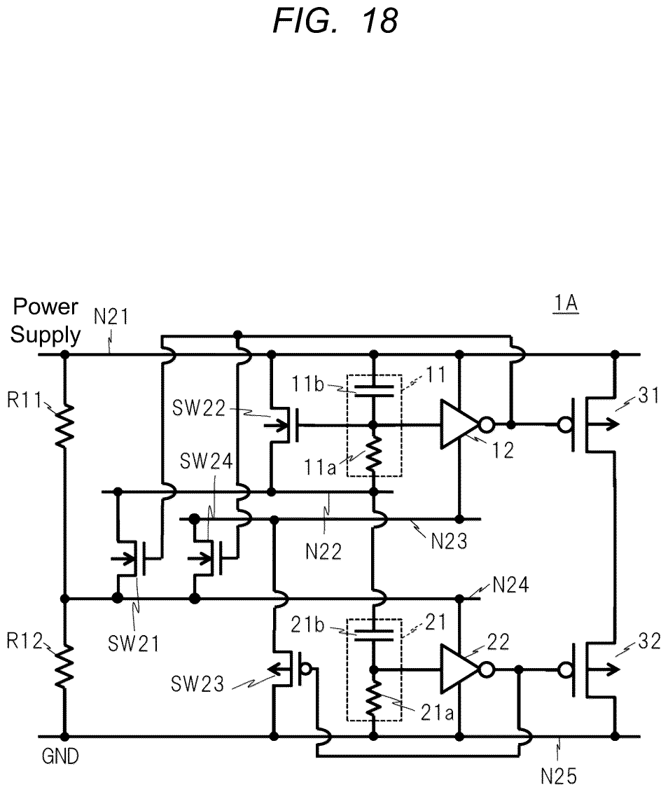

Next, the third modified example of this embodiment will be described. FIG. 18 is a circuit diagram in which each switch is configured using a type of MOSFET not used in FIG. 17, as shown in the table of FIG. 16. In other words, it is another example of a circuit configuration according to the table of FIG. 16. Of course, any circuit configuration according to the table of FIG. 16 may be used, not limited to FIG. 18. In FIG. 18, switch SW21 is composed of an nMOS transistor, and the gate is connected to the output of the inverter 12. Switch SW22 is composed of an nMOS transistor, and the gate is connected to the output of the detection circuit 11. Switch SW23 is composed of a pMOS transistor, and the gate is connected to the output of the inverter 22. Switch SW24 is composed of an nMOS transistor, and the gate is connected to the output of the inverter 12.

Switch SW21 has the gate connection as described above, with the drain connected to the power supply node N22 and the source connected to the power supply node N24. Switch SW21 turns on when the inverter 12 outputs a Hi level. In other words, switch SW21 turns on when the detection circuit 11 does not detect ESD application.

Switch SW22 has the gate connection as described above, with the drain connected to the power supply node N21 and the source connected to the power supply node N22. Switch SW22 turns on when the detection circuit 11 outputs a Hi level. In other words, switch SW22 turns on when the detection circuit 11 detects ESD application.

Switch SW23 has the gate connection as described above, with the source connected to the power supply node N23 and the drain connected to the power supply node N25. Switch SW23 turns on when the inverter 22 outputs a Lo level. In other words, switch SW23 turns on when the detection circuit 21 detects ESD application.

Switch SW24 has the gate connection as described above, with the drain connected to the power supply node N23 and the source connected to the power supply node N24. Switch SW24 turns on when the inverter 12 outputs a Hi level. In other words, switch SW24 turns on when the detection circuit 11 does not detect ESD application.

### Fourth Modified Example

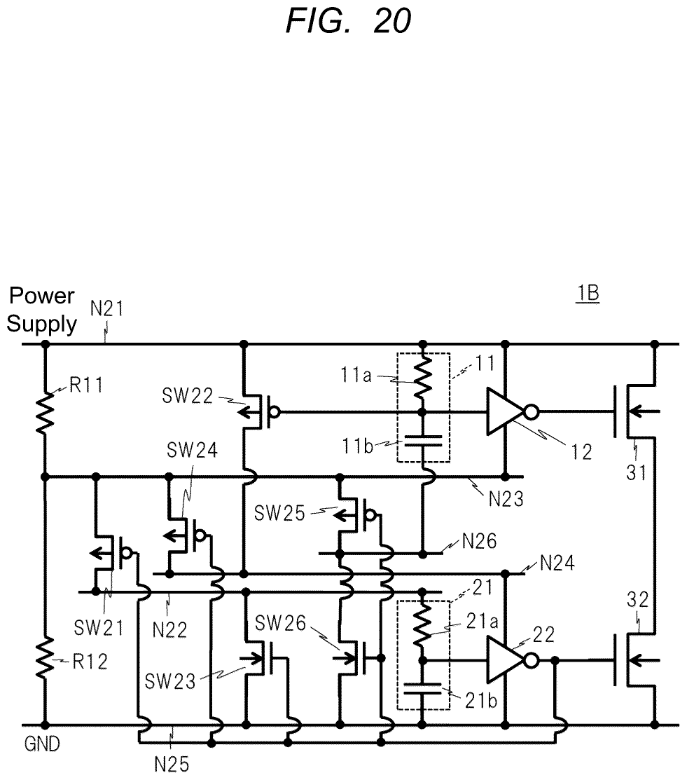

Next, the fourth modified example of this embodiment will be described. In the circuit FIG. 14, the low potential side power supply node of the detection circuit 11 and the high potential side power supply node of the detection circuit 21 were a common node, but FIG. 20 is a circuit diagram when these are separated into different nodes. FIG. 20 is a circuit diagram of a semiconductor device 1B in which the low potential side power supply node of the detection circuit 11 and the high potential side power supply node of the detection circuit 21 are separated from the circuit of FIG. 14.

In FIG. 20, the low potential side power supply node of the detection circuit 11 is newly added as the power supply node N26 compared to the circuit of FIG. 14. In other words, the other end of the capacitance element 11b is connected to the power supply node N26. That is, the power supply node N26 corresponds to the eighth power supply node. Also, the power supply node N22, to which one end of the resistor element 21a is connected, corresponds to the ninth power supply node.

In FIG. 20, switches SW25 and SW26 are added to the circuit of FIG. 14. Switch SW25 is composed of a pMOS transistor. The source of switch SW25 is connected to the power supply node N23, and the drain is connected to the power supply node N26. The gate of switch SW25 is connected to the output of the inverter 12. Switch SW25 turns on when the inverter 12 outputs a Lo level. In other words, switch SW25 turns on when the inverter 12 does not detect ESD application.

Switch SW26 is composed of an nMOS transistor. The drain of switch SW26 is connected to the power supply node N26, and the source is connected to the power supply node N25. The gate of switch SW26 is connected to the output of the inverter 22. Switch SW26 turns on when the inverter 22 outputs a Hi level. In other words, switch SW26 turns on when the inverter 22 detects ESD application.

That is, switch SW25 corresponds to the fifth switching circuit, and switch SW26 corresponds to the sixth switching circuit.

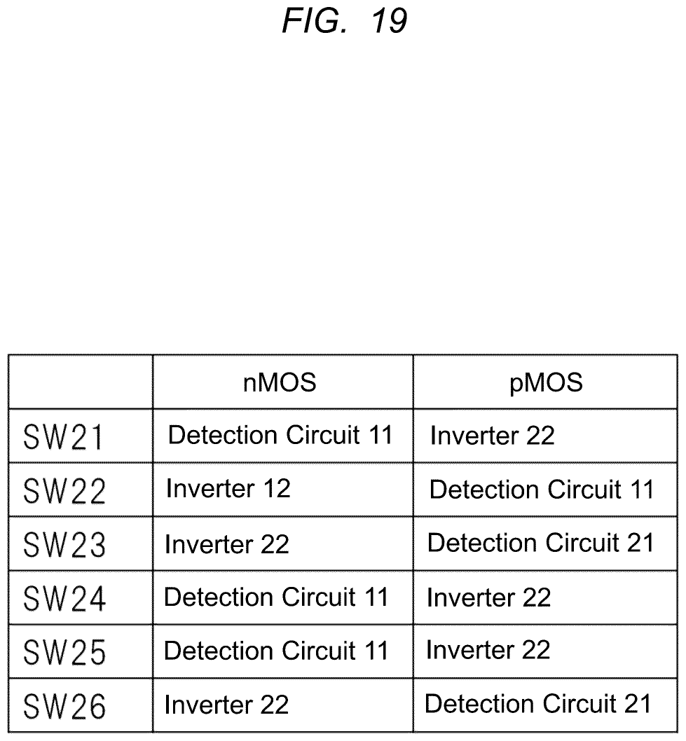

In this modified example as well, switches SW21, SW22, SW23, SW24, SW25, and SW26 can be composed of transistors (MOSFETs). As with the above-described embodiments and modified examples, the circuit operation and withstand voltage are limited to the 64 combinations shown in the table of FIG. 19.

FIG. 19 summarizes in tabular form the detection circuits or inverters connected to the gates when nMOS transistors and pMOS transistors are used for each switch, similar to FIGS. 13, 16, etc. For example, in the circuit shown in FIG. 20, as described above, switch SW21 is composed of a pMOS transistor, and the output of the inverter 22 is connected to the gate. Additionally, switch SW22 is composed of a pMOS transistor, and the output of the detection circuit 11 is connected to the gate. Furthermore, switch SW23 is composed of an nMOS transistor, and the output of the inverter 22 is connected to the gate. Moreover, switch SW24 is composed of a pMOS transistor, and the output of the inverter 22 is connected to the gate. Also, switch SW25 is composed of a pMOS transistor, and the output of the inverter 22 is connected to the gate. Additionally, switch SW26 is composed of an nMOS transistor, and the output of the inverter 22 is connected to the gate.

That is, switch SW21 is switched based on the output signal of the detection circuit 11 or the inverter 22. Also, switch SW22 is switched based on the output signal of the detection circuit 11 or the inverter 12. Additionally, switch SW23 is switched based on the output signal of the detection circuit 21 or the inverter 22. Furthermore, switch SW24 is switched based on the output signal of the detection circuit 11 or the inverter 22. Moreover, switch SW25 is switched based on the output signal of the detection circuit 11 or the inverter 22. Additionally, switch SW26 is switched based on the output signal of the detection circuit 21 or the inverter 22.

For the same reasons as described in the first embodiment, it is preferable that switch SW22 is a pMOS transistor as shown in FIG. 19. It is also preferable that switch SW23 is an nMOS transistor as shown in FIG. 19. Similarly, it is preferable that switch SW26 is an nMOS transistor as shown in FIG. 19.

In the circuit of FIG. 20, when ESD application is not detected, switches SW21, SW24, and SW25 are turned on, while switches SW22, SW23, and SW26 are turned off. As a result, power nodes N22, N23, N24, and N26 are electrically connected, and a divided potential from the voltage divider circuit is supplied to these nodes. Meanwhile, power node N21 is electrically disconnected from power node N24, power node N22 is electrically disconnected from power node N25, and power node N26 is electrically disconnected from power node N25.

On the other hand, when ESD application is detected in the circuit of FIG. 20, switches SW22, SW23, and SW26 are turned on, while switches SW21, SW24, and SW25 are turned off. As a result, power node N21 is electrically connected to power node N24, and the potential of the high-potential side power node of inverter 22 rises to approximately the same level as the power line. Additionally, power node N22 is electrically connected to power node N25, and the potential of the high-potential side power node of detection circuit 21 drops to approximately the same level as GND. Furthermore, power node N25 is electrically connected to power node N26, and the potential of the low-potential side power node of detection circuit 11 drops to approximately the same level as GND. Moreover, the potential of the low-potential side power of inverter 12 is applied with the output potential (Vesd/2) of the voltage divider circuit.

Additionally, when ESD application is detected, power node N23 is electrically disconnected from power node N22, power node N23 is electrically disconnected from power node N24, and power node N23 is electrically disconnected from power node N26.

Therefore, the circuit of FIG. 20 can operate similarly to the circuit of FIG. 14 (FIG. 10). In other words, the gate-source voltage Vgs of the nMOS transistors constituting inverters 12 and 22 can be maintained without enlargement, thereby maintaining the output of inverter 12.

### Fifth Modified Example

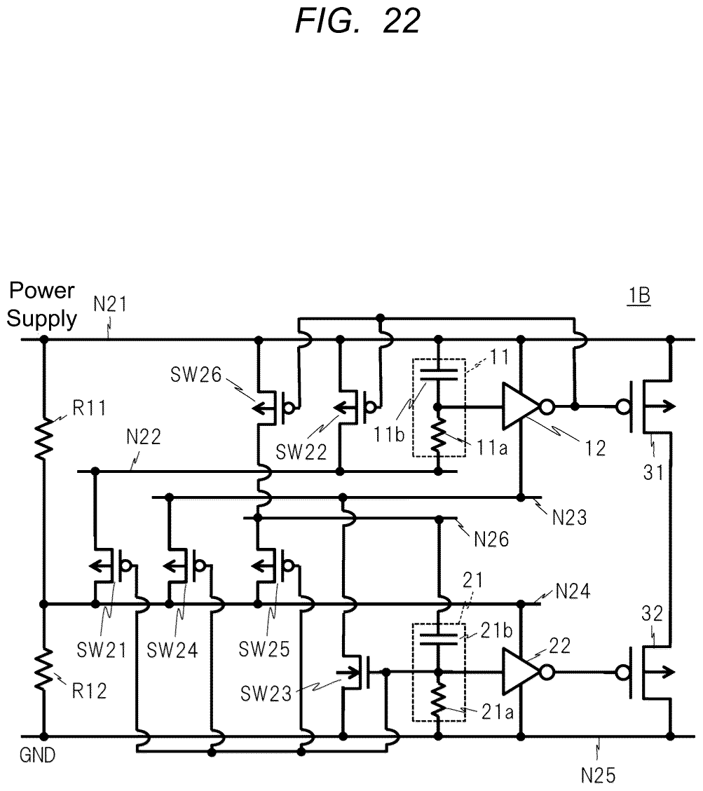

Next, the fifth modified example of this embodiment will be described. FIG. 22 is a circuit diagram where the protection transistors 31 and 32 in the circuit of FIG. 20 are configured as pMOS transistors. In the circuit of FIG. 22, the configuration of detection circuits 11 and 21 and switches SW21, SW22, SW23, SW24, SW25, and SW26 differ from those in FIG. 20.

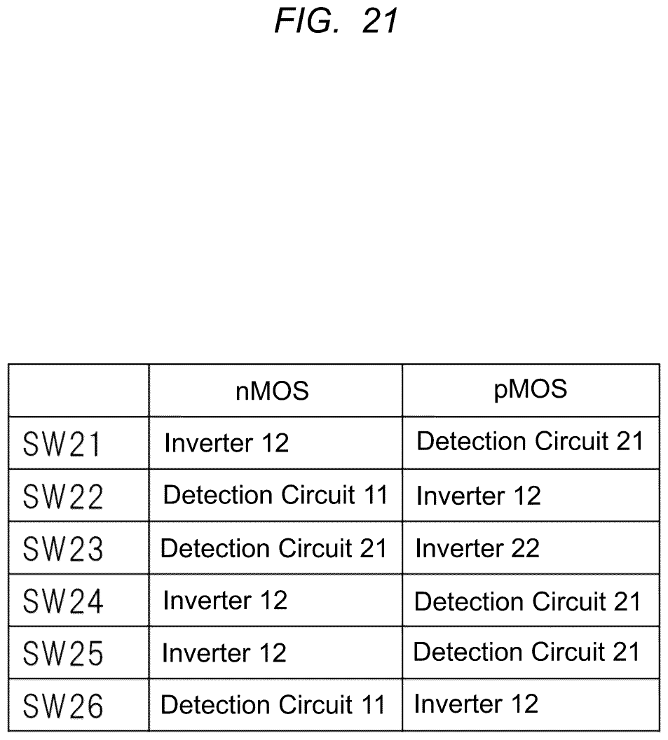

As described in the table of FIG. 19, switches SW21, SW22, SW23, SW24, SW25, and SW26 can be configured with transistors (MOSFETs). This is also true when the protection transistors 31 and 32 are configured as pMOS transistors, and the circuit operation and withstand voltage are limited to the 64 combinations shown in the table of FIG. 21.

FIG. 21 summarizes in tabular form the detection circuits or inverters connected to the gates when each switch is configured as an nMOS transistor or a pMOS transistor, similar to FIG. 19. For example, in the circuit shown in FIG. 22, switch SW21 is configured as a pMOS transistor, and the output of detection circuit 21 is connected to its gate. Similarly, switch SW22 is configured as a pMOS transistor, and the output of inverter 12 is connected to its gate. Switch SW23 is configured as an nMOS transistor, and the output of detection circuit 21 is connected to its gate. Switch SW24 is configured as a pMOS transistor, and the output of detection circuit 21 is connected to its gate. Switch SW25 is configured as a pMOS transistor, and the output of detection circuit 21 is connected to its gate. Switch SW26 is configured as a pMOS transistor, and the output of inverter 12 is connected to its gate.

That is, switch SW21 is switched based on the output signal of inverter 12 or detection circuit 21. Similarly, switch SW22 is switched based on the output signal of detection circuit 11 or inverter 12. Switch SW23 is switched based on the output signal of detection circuit 21 or inverter 22. Switch SW24 is switched based on the output signal of inverter 12 or detection circuit 21. Switch SW25 is switched based on the output signal of inverter 12 or detection circuit 21. Switch SW26 is switched based on the output signal of detection circuit 11 or inverter 12.

For the same reasons as described in the first embodiment, it is preferable that switch SW22 is a pMOS transistor, as shown in FIG. 22. Similarly, it is preferable that switch SW23 is an nMOS transistor, as shown in FIG. 22. It is also preferable that switch SW26 is a pMOS transistor, as shown in FIG. 22.

In detection circuit 11, the connection relationship between capacitance element 11b and resistance element 11a is reversed compared to FIG. 20. That is, one end of capacitance element 11b is connected to power node N21, and the other end is connected to one end of resistance element 11a. The other end of resistance element 11a is connected to power node N22. The connection point between capacitance element 11b and resistance element 11a is connected to the input of inverter 12.

In detection circuit 21, the connection relationship between capacitance element 21b and resistance element 21a is reversed compared to FIG. 20. That is, one end of capacitance element 21b is connected to power node N26, and the other end is connected to one end of resistance element 21a. The other end of resistance element 21a is connected to power node N25. The connection point between capacitance element 21b and resistance element 21a is connected to the input of inverter 22.

Switch SW21 is configured as a pMOS transistor, as described above. The source of switch SW21 is connected to power node N22, and the drain is connected to power node N24. The output of detection circuit 21 is connected to the gate of switch SW21. Switch SW21 turns on when detection circuit 21 outputs a Lo level. In other words, switch SW21 turns on when detection circuit 21 does not detect ESD application.

Switch SW22 is configured as a pMOS transistor, as described above. The source of switch SW22 is connected to power node N21, and the drain is connected to power node N22. The output of inverter 12 is connected to the gate of switch SW22. Switch SW22 turns on when inverter 12 outputs a Lo level. In other words, switch SW22 turns on when detection circuit 11 detects ESD application.

Switch SW23 is configured as an nMOS transistor, as described above. The drain of switch SW23 is connected to power node N23, and the source is connected to power node N25. The output of detection circuit 21 is connected to the gate of switch SW23. Switch SW23 turns on when detection circuit 21 outputs a Hi level. In other words, switch SW23 turns on when detection circuit 21 detects ESD application.

Switch SW24 is configured as a pMOS transistor, as described above. The source of switch SW24 is connected to power node N23, and the drain is connected to power node N24. The output of detection circuit 21 is connected to the gate of switch SW24. Switch SW24 turns on when detection circuit 21 outputs a Lo level. In other words, switch SW24 turns on when detection circuit 21 does not detect ESD application.

Switch SW25 is configured as a pMOS transistor, as described above. The source of switch SW25 is connected to power node N26, and the drain is connected to power node N24. The output of detection circuit 21 is connected to the gate of switch SW25. Switch SW25 turns on when detection circuit 21 outputs a Lo level. In other words, switch SW24 turns on when detection circuit 21 does not detect ESD application.

Switch SW26 is configured as a pMOS transistor, as described above. The source of switch SW26 is connected to power node N21, and the drain is connected to power node N26. The output of inverter 12 is connected to the gate of switch SW26. Switch SW26 turns on when inverter 12 outputs a Lo level. In other words, switch SW26 turns on when detection circuit 11 detects ESD application.

The circuit of FIG. 22, aside from changes in logic levels and some circuit modifications due to the change of protection transistors 31 and 32 to pMOS transistors, operates similarly to the circuit of FIG. 20. That is, during ESD application, detection circuits 11 and 21 output a Hi level indicating ESD application, and inverters 12 and 22 output a Lo level. Therefore, protection transistors 31 and 32 turn on and discharge the current associated with ESD application. Thus, the circuit of FIG. 22 can achieve the same effects as the circuit of FIG. 20.

The configuration shown in FIG. 22 corresponds to detection circuit 21 as the first detection circuit, inverter 22 as the first drive circuit, detection circuit 11 as the second detection circuit, and inverter 12 as the second drive circuit. Therefore, trigger circuit 20 corresponds to the first trigger circuit, and trigger circuit 10 corresponds to the second trigger circuit. Additionally, the power node N25 corresponds to the first and third power nodes, the power node N24 corresponds to the fourth power node, the power node N23 corresponds to the sixth power node, the power node N21 corresponds to the fifth and seventh power nodes, the power node N26 corresponds to the eighth power node, and the power node N22 corresponds to the ninth power node. Furthermore, switch SW21 corresponds to the first switching circuit, switch SW23 corresponds to the second switching circuit, switch SW22 corresponds to the third switching circuit, switch SW24 corresponds to the fourth switching circuit, switch SW25 corresponds to the fifth switching circuit, and switch SW26 corresponds to the sixth switching circuit.

It goes without saying that in the fourth and fifth modified examples, as long as the circuit configuration follows the combination of tables in FIGS. 19 and 21, it may be a circuit configuration other than those in FIGS. 20 and 22.

According to the above configuration, semiconductor device 1A has the low potential side power node of detection circuit 11 and the low potential side power node of the inverter 12 as separate nodes, and the high potential side power node of detection circuit 21 and the high potential side power node of the inverter 12 as separate nodes. Therefore, the high potential side power node of the inverter 22 is electrically connected to the power line, and its potential rises to approximately the same level as the power line. Additionally, the high potential side power node of the detection circuit 21 is electrically connected to GND, and its potential decreases to approximately the same level as GND. Thus, while maintaining the high potential of the high potential side power node of the inverter 22, i.e., the gate potential of the protection transistor 32, the potential of the high potential side power node of the detection circuit 21 can be lowered to maintain the Hi output of the inverter 22.

Furthermore, the low potential side power node of the inverter 12 rises to approximately the same level as the divided potential by the voltage divider circuit. Therefore, by not excessively lowering the potential of the low potential side power node of the inverter 12, the expansion of the gate-source voltage Vgs of the inverter 12 can be suppressed, maintaining the Hi output of the inverter 12.

### Third Embodiment

Next, the third embodiment will be described. In the following, explanations of overlapping parts with the aforementioned embodiments will be omitted in principle.

In the first and second embodiments described above, the number of series connections (vertical stacking number) of the protection transistors was 2, but it may be 3 or more. In this embodiment, as an example, a circuit with a vertical stacking number of 3 is shown for the second embodiment (circuit of FIG. 14).

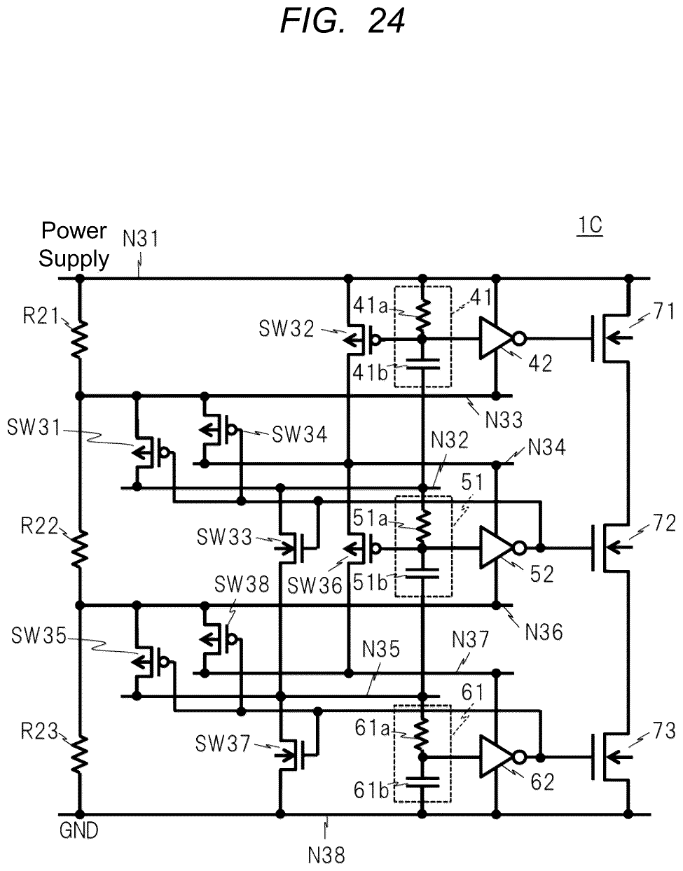

A circuit diagram of the semiconductor device according to this embodiment is shown in FIG. 24. FIG. 24 is a circuit diagram of the electrostatic protection circuit portion of the semiconductor device 1C according to this embodiment. The semiconductor device 1C includes resistors R21, R22, and R23, detection circuits 41, 51, and 61, inverters 42, 52, and 62, protection transistors 71, 72, and 73, and switches SW31, SW32, SW33, SW34, SW35, SW36, SW37, and SW38.

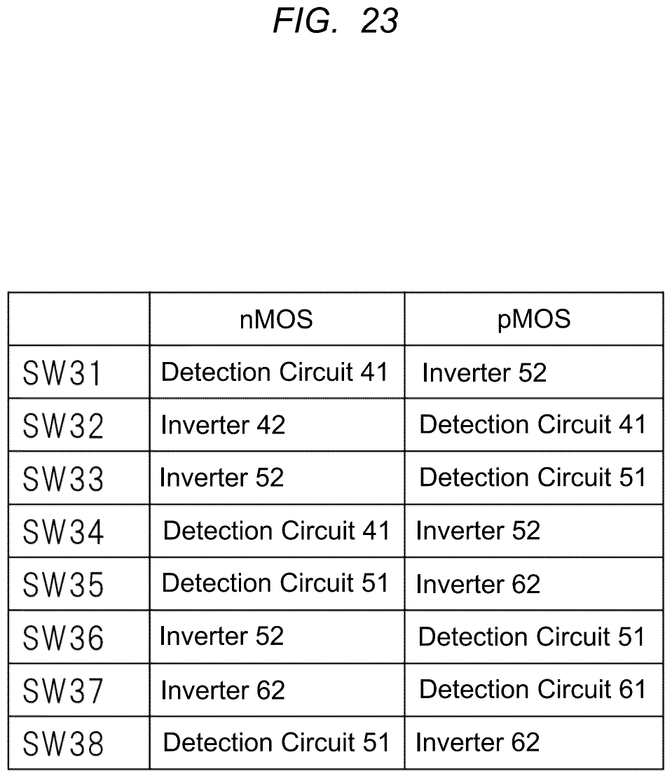

As in the first and second embodiments, switches SW31, SW32, SW33, SW34, SW35, SW36, SW37, and SW38 can be configured with transistors (MOSFETs) as shown in FIG. 24. In this case, each switch can be configured with either nMOS or pMOS transistors but is limited to 256 combinations as shown in the table in FIG. 23 from the perspective of circuit operation and breakdown voltage.

FIG. 23 summarizes in table form the detection circuit or inverter connected to the gate when each switch is configured with nMOS or pMOS transistors. For example, in the circuit shown in FIG. 24, switch SW31 is configured with a pMOS transistor, and the output of inverter 52 is connected to its gate. Also, switch SW32 is configured with a pMOS transistor, and the output of detection circuit 41 is connected to its gate. Furthermore, switch SW33 is configured with an nMOS transistor, and the output of inverter 52 is connected to its gate. Additionally, switch SW34 is configured with a pMOS transistor, and the output of inverter 52 is connected to its gate.

Moreover, switch SW35 is configured with a pMOS transistor, and the output of inverter 62 is connected to its gate. Also, switch SW36 is configured with a pMOS transistor, and the output of detection circuit 51 is connected to its gate. Furthermore, switch SW37 is configured with an nMOS transistor, and the output of inverter 62 is connected to its gate. Additionally, switch SW38 is configured with a pMOS transistor, and the output of inverter 62 is connected to its gate.

That is, switch SW31 is switched based on the output signal of detection circuit 41 or inverter 52. Also, switch SW32 is switched based on the output signal of detection circuit 41 or inverter 42. Furthermore, switch SW33 is switched based on the output signal of detection circuit 51 or inverter 52. Additionally, switch SW34 is switched based on the output signal of detection circuit 41 or inverter 52.

Moreover, switch SW35 is switched based on the output signal of detection circuit 51 or inverter 62. Also, switch SW36 is switched based on the output signal of detection circuit 51 or inverter 52. Furthermore, switch SW37 is switched based on the output signal of detection circuit 61 or inverter 62. Additionally, switch SW38 is switched based on the output signal of detection circuit 51 or inverter 62.

For the same reasons as explained in the first embodiment, it is preferable that switch SW32 is a pMOS transistor as shown in FIG. 24. Also, it is preferable that switch SW33 is an nMOS transistor as shown in FIG. 24. Furthermore, it is preferable that switch SW36 is a pMOS transistor as shown in FIG. 24. Additionally, it is preferable that switch SW37 is an nMOS transistor as shown in FIG. 24.

Resistors R21, R22, and R23 form a voltage divider circuit with three resistors connected in series between the power supply and GND. In the circuit of FIG. 24, the voltage divided by each resistor is supplied to power nodes N33 and N36. Power node N33 is supplied with ⅔ of the power supply voltage (the potential difference between the power line and GND), and power node N36 is supplied with ⅓ of the power supply voltage. Note that resistors R21, R22, and R23 are not limited to resistor elements and may be configured with transistors. Also, as long as the potential difference that allows inverters 42 and 52 to operate normally is ensured, the division ratio does not necessarily have to be ⅔ or ⅓ (1:1:1).

Detection circuits 41, 51, and 61, like detection circuits 11 and 21 in FIGS. 5 and 14, are circuits that detect ESD application to the power line and are similarly composed of resistor and capacitor elements. Inverters 42, 52, and 62 drive protection transistors 71, 72, and 73 based on the detection results of detection circuits 41, 51, and 61. That is, detection circuit 41 and inverter 42 form a trigger circuit corresponding to protection transistor 71, detection circuit 51 and inverter 52 form a trigger circuit corresponding to protection transistor 72, and detection circuit 61 and inverter 62 form a trigger circuit corresponding to protection transistor 73.

Detection circuit 41 is connected between the power line (power node N31) and power node N32. Power node N31 is the high potential side power node for detection circuit 41 and inverter 42, and power node N32 is the low potential side power node for detection circuit 41. Detection circuit 41 is composed of a resistor element 41a and a capacitor element 41b. Resistor element 41a and capacitor element 41b are connected in series between power nodes N31 and N32. In other words, one end of resistor element 41a is connected to power node N31, and the other end is connected to one end of capacitor element 41b. The other end of capacitor element 41b is connected to power node N32. The connection point of resistor element 41a and capacitor element 41b is connected to the input of inverter 42.

Inverter 42 is connected between power nodes N31 and N33. Power node N33 is the low potential side power node for inverter 42.

Detection circuit 51 is connected between power nodes N32 and N35. Power node N32 is common with the low potential side power node of detection circuit 41 and is also the high potential side power node for detection circuit 51. Power node N35 is the low potential side power node for detection circuit 51. Detection circuit 51 is composed of a resistor element 51a and a capacitor element 51b. Resistor element 51a and capacitor element 51b are connected in the series between power nodes N32 and N35. In other words, one end of resistor element 51a is connected to power node N32, and the other end is connected to one end of capacitor element 51b. The other end of capacitor element 51b is connected to power node N35. The connection point of resistor element 51a and capacitor element 51b is connected to the input of inverter 52.

Inverter 52 is connected between power nodes N34 and N36. Power node N34 is the high potential side power node for inverter 52. Power node N36 is the low potential side power node for inverter 52.

The detection circuit 61 is connected between the power supply node N35 and the power supply node N38. The power supply node N35 is common with the low potential side power supply node of detection circuit 51 and is also the high potential side power supply node of detection circuit 61. The power supply node N38 is the low potential side power supply node for the detection circuit 61 and the inverter 62. The detection circuit 61 is composed of a resistance element 61a and a capacitance element 61b. The resistance element 61a and the capacitance element 61b are connected in series between the power supply node N35 and the power supply node N38. In other words, one end of the resistance element 61a is connected to the power supply node N35, and the other end is connected to one end of the capacitance element 61b. The other end of the capacitance element 61b is connected to the power supply node N38. The connection point between the resistance element 61a and the capacitance element 62b is connected to the input of the inverter 62.

Inverter 62 is connected between the power supply node N37 and the power supply node N38. The power supply node N37 is the high potential side power supply node for the inverter 62.

Switch SW31 electrically connects or disconnects the power supply node N33 and the power supply node N32. Switch SW32 electrically connects or disconnects the power supply node N31 and the power supply node N34. Switch SW33 electrically connects or disconnects the power supply node N32 and the power supply node N35. Switch SW34 electrically connects or disconnects the power supply node N33 and the power supply node N34. Switch SW35 electrically connects or disconnects the power supply node N36 and the power supply node N35. Switch SW36 electrically connects or disconnects the power supply node N34 and the power supply node N37. Switch SW37 electrically connects or disconnects the power supply node N35 and the power supply node N38. Switch SW38 electrically connects or disconnects the power supply node N36 and the power supply node N37.

Switch SW31 is composed of a pMOS transistor as described above. The source of switch SW31 is connected to the power supply node N33, and the drain is connected to the power supply node N32. The output of the inverter 52 is connected to the gate of switch SW31. Switch SW31 turns on when the inverter 52 outputs a Lo level. In other words, switch SW31 turns on when the detection circuit 51 does not detect ESD application. When switch SW31 turns on, as described above, it electrically connects the power supply node N33 and the power supply node N32. On the other hand, when the detection circuit 51 detects ESD application and the inverter 52 outputs a Hi level, it turns off. When switch SW31 turns off, it electrically disconnects the power supply node N33 and the power supply node N32.

Switch SW32 is composed of a pMOS transistor as described above. The source of switch SW32 is connected to the power supply node N31, and the drain is connected to the power supply node N34. The connection point of the resistance element 41a and the capacitance element 41b, that is, the output of the detection circuit 41, is connected to the gate of switch SW32. Switch SW32 turns on when the detection circuit 41 outputs a Lo level. In other words, switch SW32 turns on when the detection circuit 41 detects ESD application. When switch SW32 turns on, as described above, it electrically connects the power supply node N31 and the power supply node N34. On the other hand, when the detection circuit 41 does not detect ESD application, it outputs a Hi level, turning off switch SW32. When switch SW32 turns off, it electrically disconnects the power supply node N31 and the power supply node N34.

Switch SW33 is composed of an nMOS transistor as described above. The drain of switch SW33 is connected to the power supply node N32, and the source is connected to the power supply node N35. The output of the inverter 52 is connected to the gate of switch SW33. Switch SW33 turns on when the inverter 52 outputs a Hi level. In other words, switch SW33 turns on when the detection circuit 51 detects ESD application. When switch SW33 turns on, as described above, it electrically connects the power supply node N32 and the power supply node N35. On the other hand, when the detection circuit 51 does not detect ESD application and the inverter 52 outputs a Lo level, it turns off. When switch SW33 turns off, it electrically disconnects the power supply node N32 and the power supply node N35.

Switch SW34 is composed of a pMOS transistor as described above. The source of switch SW34 is connected to the power supply node N33, and the drain is connected to the power supply node N34. The output of the inverter 52 is connected to the gate of switch SW34. Switch SW34 turns on when the inverter 52 outputs a Lo level. In other words, switch SW34 turns on when the detection circuit 51 does not detect ESD application. When switch SW34 turns on, as described above, it electrically connects the power supply node N33 and the power supply node N34. On the other hand, when the detection circuit 51 detects ESD application and the inverter 52 outputs a Hi level, it turns off. When switch SW34 turns off, it electrically disconnects the power supply node N33 and the power supply node N34.

Switch SW35 is composed of a pMOS transistor as described above. The source of switch SW35 is connected to the power supply node N36, and the drain is connected to the power supply node N35. The output of the inverter 62 is connected to the gate of switch SW35. Switch SW35 turns on when the inverter 62 outputs a Lo level. In other words, switch SW35 turns on when the detection circuit 61 does not detect ESD application. When switch SW35 turns on, as described above, it electrically connects the power supply node N36 and the power supply node N35. On the other hand, when the detection circuit 51 detects ESD application and the inverter 52 outputs a Hi level, it turns off. When switch SW35 turns off, it electrically disconnects the power supply node N36 and the power supply node N35.

Switch SW36 is composed of a pMOS transistor as described above. The source of switch SW36 is connected to the power supply node N34, and the drain is connected to the power supply node N37. The connection point of the resistance element 51a and the capacitance element 51b, that is, the output of the detection circuit 51, is connected to the gate of switch SW36. Switch SW36 turns on when the detection circuit 51 outputs a Lo level. In other words, switch SW36 turns on when the detection circuit 51 detects ESD application. When switch SW36 turns on, as described above, it electrically connects the power supply node N34 and the power supply node N37. On the other hand, when the detection circuit 51 does not detect ESD application, it outputs a Hi level, turning off switch SW36. When switch SW36 turns off, it electrically disconnects the power supply node N34 and the power supply node N37.

Switch SW37 is composed of an nMOS transistor as described above. The drain of switch SW37 is connected to the power supply node N35, and the source is connected to the power supply node N38. The output of the inverter 62 is connected to the gate of the switch SW37. Switch SW37 turns on when the inverter 62 outputs a Hi level. In other words, switch SW37 turns on when the detection circuit 61 detects ESD application. When switch SW37 turns on, as described above, it electrically connects the power supply node N35 and the power supply node N38. On the other hand, when the detection circuit 61 does not detect ESD application and the inverter 62 outputs a Lo level, it turns off. When switch SW37 turns off, it electrically disconnects the power supply node N35 and the power supply node N38.

Switch SW38 is composed of a pMOS transistor as described above. The source of switch SW38 is connected to the power supply node N36, and the drain is connected to the power supply node N37. The output of the inverter 62 is connected to the gate of switch SW38. Switch SW38 turns on when inverter 62 outputs a low level. In other words, switch SW38 turns on when detection circuit 61 does not detect ESD application. When switch SW38 turns on, as mentioned above, it electrically connects power nodes N36 and N37. On the other hand, when detection circuit 61 does not detect ESD applications and inverter 62 outputs a high level, it turns off. When switch SW38 turns off, it electrically disconnects power nodes N36 and N37.

In the circuit of FIG. 24, when ESD application is not detected, switches SW31, SW34, SW35, and SW38 turn on, and switches SW32, SW33, SW36, and SW37 turn off. Therefore, power nodes N33, N34, and N32 are electrically connected, and power nodes N36, N37, and N35 are electrically connected. Consequently, power nodes N33, N34, and N32 become a divided potential (⅔ of the power supply voltage) by the voltage divider circuit, and power nodes N36, N37, and N35 become a divided potential (⅓ of the power supply voltage) by the voltage divider circuit. Thus, when power is turned on (when ESD application is not detected), the breakdown voltage of protection transistors 71, 72, and 73 can be alleviated.

On the other hand, when ESD application is detected, switches SW31, SW34, SW35, and SW38 turn off, and switches SW32, SW33, SW36, and SW37 turn on. Therefore, power nodes N31, N34, and N37 are electrically connected, and power nodes N32, N35, and N38 are electrically connected. Consequently, power nodes N34 and N37 become approximately the same potential as the power line, and power nodes N32 and N35 become approximately the same potential as GND. Thus, when ESD application is detected, the high potential side power supply of inverters 52 and 62 can be raised to a potential similar to the power line. Additionally, the high potential side power supply of detection circuits 51 and 61 can be lowered to a potential similar to GND. Therefore, similar to the circuit in FIG. 14, inverters 42, 52, and 62 can maintain a high output.

In the circuit of FIG. 24, if protection transistor 71 is regarded as the first protection transistor and protection transistor 72 as the second protection transistor, detection circuit 41 becomes the first detection circuit, inverter 42 becomes the first drive circuit, detection circuit 51 becomes the second detection circuit, and inverter 52 becomes the second drive circuit. Then, switch SW31 becomes the first switching circuit, switch SW32 becomes the second switching circuit, switch SW33 becomes the third switching circuit, and switch SW34 becomes the fourth switching circuit. Then, power node N31 becomes the first and third power nodes, power node N32 becomes the second power node, power node N33 becomes the fourth power node, power node N35 becomes the fifth power node, power node N34 becomes the sixth power node, and power node N36 becomes the seventh power node.

Also, if protection transistor 72 is regarded as the first protection transistor and protection transistor 73 as the second protection transistor, detection circuit 51 becomes the first detection circuit, inverter 52 becomes the first drive circuit, detection circuit 61 becomes the second detection circuit, and inverter 62 becomes the second drive circuit. Then, switch SW35 becomes the first switching circuit, switch SW36 becomes the second switching circuit, switch SW37 becomes the third switching circuit, and switch SW38 becomes the fourth switching circuit. Then, power node N32 becomes the first power node, power node N35 becomes the second power node, power node N34 becomes the third power node, power node N36 becomes the fourth power node, power node N38 becomes the fifth and seventh power nodes, and power node N37 becomes the sixth power node.

It goes without saying that even in the third embodiment, as long as the circuit configuration follows the combination in the table of FIG. 23, it may be a circuit configuration other than FIG. 24. Also, in the circuit of FIG. 24, the protection transistors may be pMOS transistors. In that case, the detection circuits and switches can be appropriately changed as in FIGS. 8, 17, etc. In such a case, it goes without saying that the selection of n-channel and p-channel for the switches should be combinable from the perspective of circuit operation and breakdown voltage.

Although the invention made by the present inventor has been specifically described based on the embodiment, it goes without saying that the present invention is not limited to the above-described embodiment, and various modifications can be made without departing from the gist thereof.

What is claimed is:

1. A semiconductor device comprising:
a first protection transistor and a second protection transistor connected in series;
a first trigger circuit connected between a first power node and a second power node, detecting the application of electrostatic discharge and controlling the first protection transistor;
a second trigger circuit connected between a third power node and a fourth power node, detecting the application of the electrostatic discharge and controlling the second protection transistor;
a first switching circuit for switching the electrical connection or disconnection between the second power node and the third power node;
a second switching circuit for switching the electrical connection or disconnection between the first power node and the third power node; and
a third switching circuit for switching the electrical connection or disconnection between the second power node and the fourth power node,
wherein when the first trigger circuit and the second trigger circuit do not detect the application of the electrostatic discharge, the first switching circuit electrically connects the second power node and the third power node, the second switching circuit electrically disconnects the first power node and the third power node, and the third switching circuit electrically disconnects the second power node and the fourth power node, and
wherein when the first trigger circuit and the second trigger circuit detect the application of the electrostatic discharge, the first switching circuit electrically disconnects the second power node and the third power node, the second switching circuit electrically connects the first power node and the third power node, and the third switching circuit electrically connects the second power node and the fourth power node.

2. The semiconductor device according to claim 1,
wherein the first trigger circuit has a first detection circuit for detecting the electrostatic discharge and a first drive circuit for driving the first protection transistor based on the detection result of the first detection circuit, and
wherein the second trigger circuit has a second detection circuit for detecting the electrostatic discharge and a second drive circuit for driving the second protection transistor based on the detection result of the second detection circuit.

3. The semiconductor device according to claim 2,
wherein the first protection transistor and the second protection transistor are composed of n-channel type MOSFETs,
wherein the first switching circuit is switched based on the output signal of the first detection circuit or the second drive circuit,
wherein the second switching circuit is switched based on the output signal of the first detection circuit or the first drive circuit, and
wherein the third switching circuit is switched based on the output signal of the second detection circuit or the second drive circuit.

4. The semiconductor device according to claim 2,
wherein the first protection transistor and the second protection transistor are composed of p-channel type MOSFETs,
wherein the first switching circuit is switched based on the output signal of the first drive circuit or the second detection circuit,
wherein the second switching circuit is switched based on the output signal of the first detection circuit or the first drive circuit, and
wherein the third switching circuit is switched based on the output signal of the second detection circuit or the second drive circuit.

5. The semiconductor device according to claim 3,
wherein the second switching circuit is composed of a p-channel type MOSFET, and
wherein the third switching circuit is composed of an n-channel type MOSFET.

6. A semiconductor device comprising:
a first protection transistor and a second protection transistor connected in series;
a first detection circuit connected between a first power node and a second power node, detecting the application of electrostatic discharge;
a first drive circuit connected between a third power node and a fourth power node, driving the first protection transistor based on the detection result of the first detection circuit;
a second detection circuit connected between the second power node and a fifth power node, detecting the application of electrostatic discharge;
a second drive circuit connected between a sixth power node and a seventh power node, driving the second protection transistor based on the detection result of the second detection circuit;
a first switching circuit for switching the electrical connection or disconnection between the second power node and the fourth power node;
a second switching circuit for switching the electrical connection or disconnection between the third power node and the sixth power node;
a third switching circuit for switching the electrical connection or disconnection between the second power node and the fifth power node; and
a fourth switching circuit for switching the electrical connection or disconnection between the fourth power node and the sixth power node,
wherein when the first detection circuit and the second detection circuit do not detect the application of the electrostatic discharge, the first switching circuit electrically connects the second power node and the fourth power node, the second switching circuit electrically disconnects the third power node and the sixth power node, the third switching circuit electrically disconnects the second power node and the fifth power node, and the fourth switching circuit electrically connects the fourth power node and the sixth power node, and
wherein when the first detection circuit and the second detection circuit detect the application of the electrostatic discharge, the first switching circuit electrically disconnects the second power node and the fourth power node, the second switching circuit electrically connects the third power node and the sixth power node, the third switching circuit electrically connects the second power node and the fifth power node, and the fourth switching circuit electrically disconnects the fourth power node and the sixth power node.

7. The semiconductor device according to claim 6,
wherein the first protection transistor and the second protection transistor are composed of n-channel type MOSFETs,
wherein the first switching circuit is switched based on the output signal of the first detection circuit or the second drive circuit,
wherein the second switching circuit is switched based on the output signal of the first detection circuit or the first drive circuit,
wherein the third switching circuit is switched based on the output signal of the second detection circuit or the second drive circuit, and
wherein the fourth switching circuit is switched based on the output signal of the first detection circuit or the second drive circuit.

8. The semiconductor device according to claim 7,
wherein the second switching circuit is composed of a p-channel type MOSFET, and
wherein the third switching circuit is composed of an n-channel type MOSFET.

9. The semiconductor device according to claim 6,
wherein the first protection transistor and the second protection transistor are composed of p-channel type MOSFETs,
wherein the first switching circuit is switched based on the output signal of the second drive circuit or the first detection circuit,
wherein the second switching circuit is switched based on the output signal of the first detection circuit or the first drive circuit,
wherein the third switching circuit is switched based on the output signal of the second detection circuit or the second drive circuit, and
wherein the fourth switching circuit is switched based on the output signal of the second drive circuit or the first detection circuit.

10. The semiconductor device according to claim 7,
wherein the second switching circuit is composed of an n-channel type MOSFET, and
wherein the third switching circuit is composed of a p-channel type MOSFET, semiconductor device.

11. The semiconductor device according to claim 6,
wherein the second power node is composed of the eighth power node to which the first detection circuit is connected and the ninth power node to which the second detection circuit is connected,
wherein the first switching circuit switches the electrical connection or disconnection between the fourth power node and the ninth power node,
wherein a fifth switching circuit that switches the electrical connection or disconnection between the fourth power node and the eighth power node,
wherein a sixth switching circuit that switches the electrical connection or disconnection between the fifth power node and the eighth power node,
wherein when the first detection circuit and the second detection circuit do not detect the application of electrostatic discharge, the first switching circuit electrically connects the fourth power node and the ninth power node, the second switching circuit electrically disconnects the third power node and the sixth power node, the third switching circuit electrically disconnects the fifth power node and the ninth power node, the fourth switching circuit electrically connects the fourth power node and the sixth power node, the fifth switching circuit electrically connects the fourth power node and the eighth power node, and the sixth switching circuit electrically disconnects the fifth power node and the eighth power node, and
wherein when the first detection circuit and the second detection circuit detect the application of electrostatic discharge, the first switching circuit electrically disconnects the fourth power node and the ninth power node, the second switching circuit electrically connects the third power node and the sixth power node, the third switching circuit electrically connects the fifth power node and the ninth power node, the fourth switching circuit electrically disconnects the fourth power node and the sixth power node, the fifth switching circuit electrically disconnects the fourth power node and the eighth power node, and the sixth switching circuit electrically connects the fifth power node and the eighth power node, semiconductor device.

12. The semiconductor device according to claim 11,
wherein the first protection transistor and the second protection transistor are composed of n-channel type MOSFETs,
wherein the first switching circuit is switched based on the output signal of the first detection circuit or the second drive circuit,
wherein the second switching circuit is switched based on the output signal of the first detection circuit or the first drive circuit,
wherein the third switching circuit is switched based on the output signal of the second detection circuit or the second drive circuit,
wherein the fourth switching circuit is switched based on the output signal of the first detection circuit or the second drive circuit,
wherein the fifth switching circuit is switched based on the output signal of the first detection circuit or the second drive circuit, and
wherein the sixth switching circuit is switched based on the output signal of the second detection circuit or the second drive circuit.

13. In the semiconductor device described in claim 12, the second switching circuit is composed of a p-channel type MOSFET, the third switching circuit is composed of an n-channel type MOSFET, and the sixth switching circuit is composed of an n-channel type MOSFET, semiconductor device.

14. The semiconductor device according to claim 11,
wherein the first protection transistor and the second protection transistor are composed of p-channel type MOSFETs,
wherein the first switching circuit is switched based on the output signal of the second drive circuit or the first detection circuit,
wherein the second switching circuit is switched based on the output signal of the first detection circuit or the first drive circuit,
wherein the third switching circuit is switched based on the output signal of the second detection circuit or the second drive circuit,
wherein the fourth switching circuit is switched based on the output signal of the second drive circuit or the first detection circuit,
wherein the fifth switching circuit is switched based on the output signal of the second drive circuit or the first detection circuit, and
wherein the sixth switching circuit is switched based on the output signal of the second detection circuit or the second drive circuit.

15. The semiconductor device according to claim 14,
wherein the second switching circuit is composed of an n-channel type MOSFET,
wherein the third switching circuit is composed of a p-channel type MOSFET, and
wherein the sixth switching circuit is composed of a p-channel type MOSFET.
